(19) United States
(12) Patent Application Publication
(10) Pub. No.: US 2015/0060975 A1
(43) Pub. Date: Mar. 5, 2015

(54) NONVOLATILE SEMICONDUCTOR MEMORY DEVICE

(71) Applicant: KABUSHIKI KAISHA TOSHIBA, Tokyo (JP)

(72) Inventors: Hiroyuki NITTA, Yokkaichi Mie (JP); Yusuke OKUMURA, Yokkaichi Mie (JP); Yuji SETTA, Kuwana Mie (JP)

(73) Assignee: KABUSHIKI KAISHA TOSHIBA, Tokyo (JP)

(21) Appl. No.: 14/191,283

(22) Filed: Feb. 26, 2014

(30) Foreign Application Priority Data
Aug. 29, 2013 (JP) 2013-178029

(51) Int. Cl. H01L 27/112

(52) U.S. Cl. CPC H01L 27/11293
USPC 257/314

(57) ABSTRACT

A nonvolatile semiconductor memory device includes first and second memory blocks which are disposed adjacent to each other in a first direction. The first and second memory blocks each include a plurality of bit lines, a plurality of word lines, which are disposed to extend in a second direction, and a memory cell, which is connected to any of the plurality of word lines. The first memory block includes a first selection gate line which is connected to one end of the memory cell, and the second memory block includes a second selection gate line in the same manner. An end portion of one end of the first selection gate line includes an L-shaped portion, and an end portion of one end of the second selection gate line includes a linear portion. A first contact is disposed on the L-shaped portion of the first selection gate.

### CROSS-REFERENCE TO RELATED APPLICATION

This application is based upon and claims the benefit of priority from Japanese Patent Application No. 2013-178029, filed Aug. 29, 2013, the entire contents of which are incorporated herein by reference.

### FIELD

Embodiments described herein relate generally to a nonvolatile semiconductor memory device.

### BACKGROUND

In a nonvolatile semiconductor memory device, in order to decrease parasitic capacitance between memory gate electrodes, an air gap is formed between gate electrodes in some cases. The air gap is formed by forming an insulating film under conditions that will tend not to bury the gate electrodes, which have a gap formed therebetween, for example, and forming the insulating layer over the gate electrodes so that a void is formed therebetween.

However, a chemical solution which is used in a cleaning process, for example, may enter into the air gap and spread through the interconnected air gaps and come in contact with a wide range of the memory cells. Exposure of the memory cells to these chemical solutions will tend to attack some of the materials in the memory cells, such as the wiring materials found in the memory cell. The unwanted exposure may cause a malfunction in the affected memory cells, due to etching of the wiring material (e.g., disconnection of wires may occur).

### DESCRIPTION OF THE DRAWINGS

FIG. 1 is an example of a block diagram schematically showing an electrical configuration of a NAND-type flash memory device.

FIG. 2 is an example of a plan view schematically showing a layout pattern of a part of a memory cell region.

FIG. 3A is an example of a plan view showing a schematic configuration of a NAND-type flash memory device according to a first embodiment, and FIG. 3B is an example of a plan view schematically showing an enlarged configuration of a part of a memory cell region.

FIG. 4 is an example of a plan view showing a layout of the NAND-type flash memory device according to the first embodiment.

FIG. 5A is an example of a longitudinal cross-sectional view showing a structure taken along line A-A of FIG. 4, and FIG. 5B is an example of a longitudinal cross-sectional view showing a structure taken along line B-B of FIG. 4.

FIG. 6 is an example of a perspective view showing a stereoscopic structure of a region D of FIG. 4.

FIG. 7 is an example of a plan view showing a layout of an intermediate step of the NAND-type flash memory device according to the first embodiment.

FIG. 8A is an example of a longitudinal cross-sectional view showing a structure taken along line A-A of FIG. 7, and FIG. 8B is an example of a longitudinal cross-sectional view showing a structure taken along line B-B of FIG. 7.

FIG. 9 is an example of a plan view showing a layout of an intermediate step of the NAND-type flash memory device according to the first embodiment.

FIG. 10A is an example of a longitudinal cross-sectional view showing a structure taken along line A-A of FIG. 9, and FIG. 10B is an example of a longitudinal cross-sectional view showing a structure taken along line B-B of FIG. 9.

FIG. 11 is an example of a plan view showing a layout of an intermediate step of the NAND-type flash memory device according to the first embodiment.

FIG. 12A is an example of a longitudinal cross-sectional view showing a structure taken along line A-A of FIG. 11, and FIG. 12B is an example of a longitudinal cross-sectional view showing a structure taken along line B-B of FIG. 11.

FIG. 13 is an example of a plan view showing a layout of an intermediate step of the NAND-type flash memory device according to the first embodiment.

FIG. 14A is an example of a longitudinal cross-sectional view showing a structure taken along line A-A of FIG. 13, and FIG. 14B is an example of a longitudinal cross-sectional view showing a structure taken along line B-B of FIG. 13.

FIG. 15 is an example of a plan view showing a layout of an intermediate step of the NAND-type flash memory device according to the first embodiment.

FIG. 16A is an example of a longitudinal cross-sectional view showing a structure taken along line A-A of FIG. 15, and FIG. 16B is an example of a longitudinal cross-sectional view showing a structure taken along line B-B of FIG. 15.

FIG. 17 is an example of a plan view showing a layout of an intermediate step of the NAND-type flash memory device according to the first embodiment.

FIG. 18A is an example of a longitudinal cross-sectional view showing a structure taken along line A-A of FIG. 17, and FIG. 18B is an example of a longitudinal cross-sectional view showing a structure taken along line B-B of FIG. 17.

FIG. 19 is an example of a plan view showing a layout of an intermediate step of the NAND-type flash memory device according to the first embodiment.

FIG. 20A is an example of a longitudinal cross-sectional view showing a structure taken along line A-A of FIG. 19, and FIG. 20B is an example of a longitudinal cross-sectional view showing a structure taken along line B-B of FIG. 19.

FIG. 21 is an example of a plan view showing a layout of an intermediate step of the NAND-type flash memory device according to the first embodiment.

FIG. 22A is an example of a longitudinal cross-sectional view showing a structure taken along line A-A of FIG. 21, and FIG. 22B is an example of a longitudinal cross-sectional view showing a structure taken along line B-B of FIG. 21.

FIG. 23 is an example of a plan view showing a layout of an intermediate step of the NAND-type flash memory device according to the first embodiment.

FIG. 24A is an example of a longitudinal cross-sectional view showing a structure taken along line A-A of FIG. 23, and FIG. 24B is an example of a longitudinal cross-sectional view showing a structure taken along line B-B of FIG. 23.

FIG. 25 is an example of a plan view showing a layout of an intermediate step of the NAND-type flash memory device according to the first embodiment.

FIG. 26A is an example of a longitudinal cross-sectional view showing a structure taken along line A-A of FIG. 25, and FIG. 26B is an example of a longitudinal cross-sectional view showing a structure taken along line B-B of FIG. 25.

FIG. 27 is an example of a plan view showing a layout of a NAND-type flash memory device according to a second embodiment.

FIG. 28 is an example of a plan view showing a layout of a NAND-type flash memory device according to a third embodiment.

FIG. 29 is an example of a plan view showing a layout of a NAND-type flash memory device according to a fourth embodiment.

FIG. 30 is an example of a longitudinal cross-sectional view taken along line C-C of FIG. 29.

### DETAILED DESCRIPTION

Embodiments of the invention provide a memory device having a layout in which a chemical solution, which is typically used during a cleaning process, is prevented from attacking portions of individual memory devices that are exposed within an air gap structure formed within the memory device during the formation process.

In general, according to one embodiment, there is provided a nonvolatile semiconductor memory device that includes a first memory block and a second memory block, which are disposed to be adjacent to each other. Each of the first memory block and the second memory block includes a plurality of bit lines, which are disposed to extend in a first direction, a plurality of word lines, which are disposed to extend in a second direction that is crosswise to the bit lines, and memory cells connected to the plurality of word lines. The first memory block includes a first selection gate transistor, which is connected to one end of the memory cells of the first memory block, and the second memory block includes a second selection gate transistor, which is connected to one end of the memory cells of the second memory block. A first selection gate line connected to the first selection gate transistor and a second selection gate line connected to the second selection gate transistor are adjacent to each other. An end portion of one end of the first selection gate includes an L-shaped portion, and an end portion of one end of the second selection gate includes a linear portion, the L-shaped portion having a first region extending in the second direction and a second region extending from the first region in the first direction at the end portion. A first contact is disposed on the L-shaped portion of the first selection gate line, and a distance in the first direction from a first edge of the first selection gate line, which is not facing the second selection gate line, to a first edge of the second selection gate line, which is not facing the first selection gate line, is equivalent to a width of the L-shaped portion, where the width is measured in the first direction from the first edge of the first selection gate line to a second edge of the second region that is opposite to the first edge of the first selection gate line.

### First Embodiment

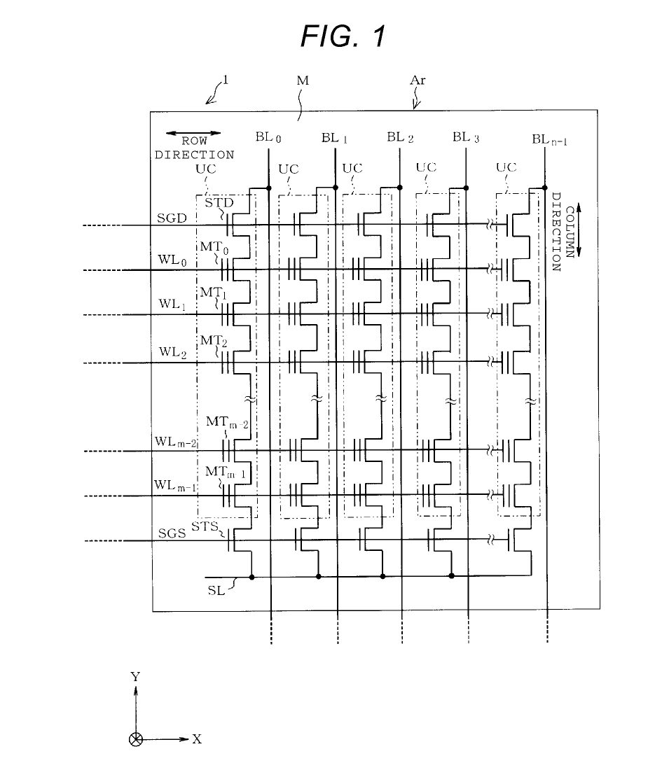

Hereinafter, a first embodiment will be described with reference to FIGS. 1 to 26B. The drawings are schematically shown and a relationship between a thickness and a planar dimension, a ratio of a thickness of each layer, and the like do not necessarily coincide with actual values. In addition, upward, downward, right, and left directions show relative directions when a circuit forming surface side of a semiconductor substrate which will be described later is set to an upper side, and do not necessarily coincide with examples having a gravity acceleration direction as a reference. In the following description, an XYZ orthogonal coordinate system is used for convenience of the description. In the coordinate system, two directions which are parallel with respect to a surface of a semiconductor substrate and which are orthogonal with each other are set to an X direction and a Y direction, in which a direction in which a word line WL extends is set to the X direction and a direction which is orthogonal thereto and in which a bit line BL extends is set to the Y direction. A direction which is orthogonal with respect to both of the X direction and the Y direction is set to a Z direction. In addition, the description of the embodiment(s) will be performed by focusing on a NAND-type flash memory device as an example of a nonvolatile semiconductor memory device and a switchable technology is appropriately mentioned.

FIG. 1 is an example of a block diagram schematically showing an electrical configuration of a NAND-type flash memory device. As shown in FIG. 1, a NAND-type flash memory device 1 includes a memory cell array Ar in which a plurality of memory cells which can perform writing and deleting of electrical data are arranged in a matrix shape or pattern.

A plurality of unit memory cells UC are arranged in the memory cell array Ar in a memory cell region M. In the unit memory cell UC, a selection gate transistor STD is provided on a connection side of bit lines BL₀ to BLₙ₋₁ and a selection gate transistor STS is provided on a source line SL side. A total of m (m=2^{k}, for example) memory cell transistors MT₀ to MTₘ₋₁ are connected to each other in series between the selection gate transistors STD and STS.

The plurality of unit memory cells UC configure a memory cell block and the plurality of memory cell blocks configure a memory cell array Ar. That is, in one block, n unit memory cells UC are arranged in parallel to each other in a row direction (X direction in FIG. 1). In the memory cell array Ar, the plurality of blocks are arranged in a column direction (Y direction in FIG. 1). For simplification of the description, one block is shown in FIG. 1.

A control line SGD is connected to a gate of the selection gate transistor STD. A word line WLₘ₋₁ is connected to a control gate of the m-th memory cell transistor MTₘ₋₁ which is connected to the bit lines BL₀ to BLₙ₋₁. A word line WL₂ is connected to a control gate of the third memory cell transistor MT₂ which is connected to the bit lines BL₀ to BLₙ₋₁. A word line WL₁ is connected to a control gate of the second memory cell transistor MT₁ which is connected to the bit lines BL₀ to BLₙ₋₁. A word line WL₀ is connected to a control gate of the first memory cell transistor MT₀ which is connected to the bit lines BL₀ to BLₙ₋₁. A control line SGS is connected to a gate of the selection gate transistor STS which is connected to the source line SL. The control line SGD, the word lines WL₀ to WLₘ₋₁, the control line SGS, and the source line SL intersect with the bit lines BL₀ to BLₙ₋₁, respectively. The bit lines BL₀ to BLₙ₋₁ are connected to a sense amplifier (not shown).

The gate electrodes of the selection gate transistors STD of the plurality of unit memory cells UC which are arranged in the row direction are electrically connected to each other by the control line SGD. In the same manner, the gate electrodes of the selection gate transistors STS of the plurality of unit memory cells UC which are arranged in the row direction are electrically connected to each other by the control line SGS. Sources of the selection gate transistors STS are commonly connected to the source line SL. Gate electrodes of the memory cell transistors MT₀ to MTₘ₋₁ of the plurality of unit memory cells UC which are arranged in the row direction are electrically connected to each other by the word lines WL₀ to WLₘ₋₁.

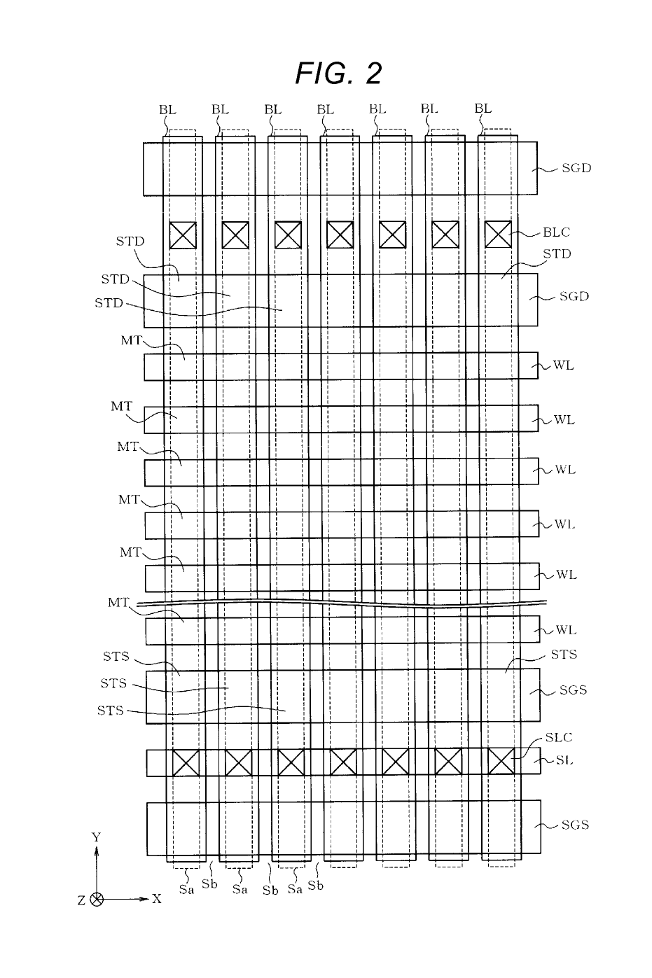

FIG. 2 is an example of a plan view schematically showing a layout pattern of a part of the memory cell region M. Hereinafter, each of the bit lines BL₀ to BLₙ₋₁ is referred to as the bit line BL, each of the word lines WL₀ to WLₘ₋₁ is referred to as the word line WL, and each of the memory cell transistors MT₀ to MTₘ₋₁ is referred to as the memory cell transistor MT.

In FIG. 2, the source line SL, the control line SGS, the word line WL, and the control line SGD are separated from each other in the Y direction and extend in the X direction and are disposed parallel to each other. The bit lines BL are separated from each other at predetermined intervals in the X direction and extend in the Y direction and are disposed parallel to each other.

An element isolation area Sb is formed to extend in the Y direction in FIG. 2. The element isolation area Sb has a shallow trench isolation (STI) structure in which an insulating film is embedded in a trench. The plurality of element isolation areas Sb are formed at predetermined intervals in the X direction. With the element isolation areas Sb, a plurality of element regions Sa, which are formed to extend along the Y direction, are separated from each other in the X direction, on a surface layer portion of the semiconductor substrate. That is, the element isolation area Sb is provided between the element regions Sa, and the plurality of regions Sa are separated from each other by the element isolation area Sb in the semiconductor substrate.

The word lines WL are formed to extend along a direction (X direction in FIG. 2) that is at an angle to (e.g., orthogonal to) the element region Sa. The plurality of word lines WL are formed at predetermined intervals in the Y direction in FIG. 2. The memory cell transistors MT are disposed on intersecting portions of the word lines WL and the element regions Sa. The plurality of memory cell transistors MT adjacent to each other in the Y direction are a part of a NAND column (memory cell string).

The selection gate transistors STS and STD are disposed on intersecting portions of the control lines SGS and SGD, and the element regions Sa. The selection gate transistors STS and STD are provided to be adjacent to both outer sides in the Y direction of the memory cell transistors MT on end portions of the NAND column.

The plurality of the selection gate transistors STS on the source line SL side are provided in the X direction, and the gate electrodes of the plurality of selection gate transistors STS are electrically connected to each other through the control line SGS. The gate electrode SG of the selection gate transistor STS is formed in a portion in which the control line SGS and the element region Sa intersect with each other. A source line contact SLC is provided in an intersecting portion of the source line SL and the bit line BL.

The plurality of selection gate transistors STD are provided in the X direction in the figure, and the gate electrodes SG (discussed below) of the selection gate transistors STD are electrically connected to each other by the control line SGD. The selection gate transistors STD are formed in a portion in which the control line SGD and the element region Sa, where the control line SGD and the element region Sa intersect with each other. Bit line contacts BLC are provided within the element region Sa, between the adjacent selection gate SGD.

Hereinabove, the basic configuration of the NAND-type flash memory device to which the first embodiment is applied, is described.

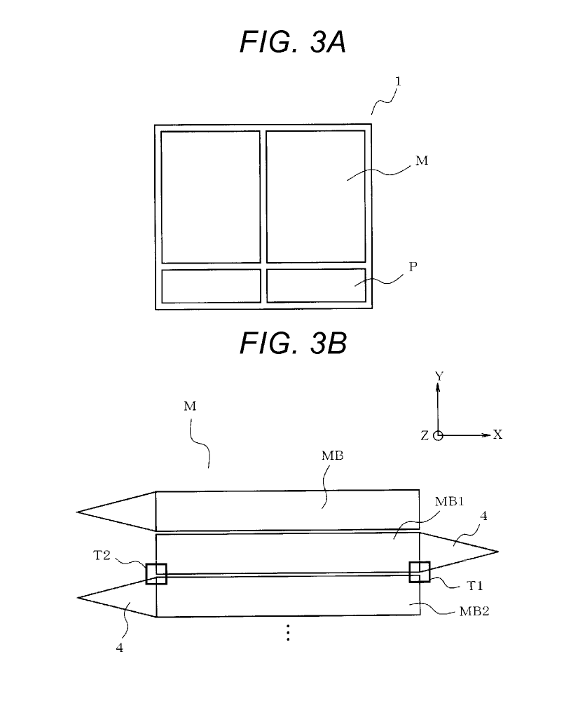

FIG. 3A is an example of a plan view showing a schematic configuration of the NAND-type flash memory device according to the embodiment. Herein, the NAND-type flash memory device 1 is shown as an example of the nonvolatile semiconductor memory device according to an embodiment. The NAND-type flash memory device 1 includes the memory cell regions M and peripheral circuit regions P.

FIG. 3B is an example of a plan view schematically showing an enlarged configuration of a part of a memory cell region M. As shown in FIG. 3B, the memory cell region M includes a plurality of memory blocks MB, which may include memory blocks MB1 and MB2. In the embodiment, the memory block MB is a rectangle which extends in the X direction in the figure, and the plurality thereof are disposed in parallel with each other in the Y direction. An extraction portion 4 is included on at least one end portion of the memory blocks MB. One extraction portion 4 is disposed in one memory block MB. The extraction portions 4 are alternately disposed on a right end and a left end of the plurality of memory blocks MB in FIG. 3B, which are parallel with each other. Herein, the memory blocks MB, to which attention is paid in this discussion, include a first memory block MB1 and a second memory block MB2. The first memory block MB1 and the second memory block MB2 are disposed adjacent to each other.

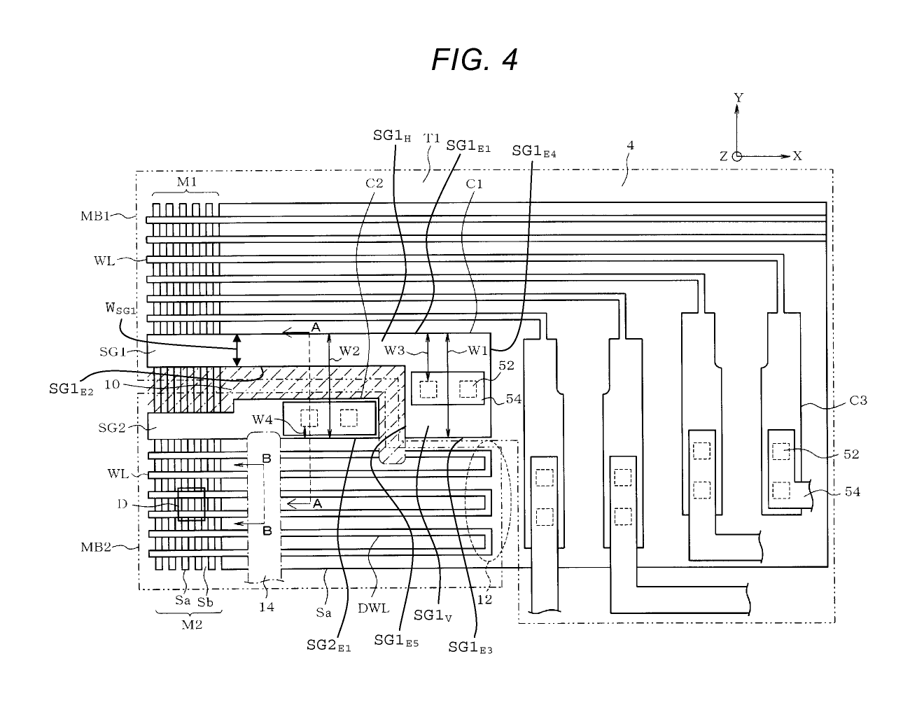

FIG. 4 is an example of a plan view showing a layout of the NAND-type flash memory device according to the first embodiment and an example of a plan view showing an enlarged first end portion T1 shown in FIG. 3B. The first memory block MB1 is disposed on the upper side in the Y direction in the figure and the second memory block MB2 is disposed on the lower side in the figure. The memory cell regions M1 and M2 are disposed on the left side of the enlarged first end portion T1 in the X direction, as illustrated in FIG. 3. In the first end portion T1, a first selection gate SG1 and a second selection gate SG2 are disposed to be adjacent to each other. The first selection gate SG1 belongs to the first memory block MB1. The second selection gate SG2 belongs to the second memory block MB2. The first selection gate SG1 and the second selection gate SG2 extend in the X direction in FIG. 4.

An inter-SG dividing region 10 is disposed between the first selection gate SG1 and the second selection gate SG2, and the first selection gate SG1 and the second selection gate SG2 are separated by the inter-SG dividing region 10. The inter-SG dividing region 10 divides the center portion of the first selection gate SG1 and the second selection gate SG2 on the left side in the figure, and extends in the X direction in the figure, is folded, or has a bend, in the Y direction in the figure, and is formed in a substantially L shape. Accordingly, in this example, the first selection gate SG1 includes a substantially L-shaped portion on the right end, and includes a wide contact formation region C1. As illustrated in FIG. 4, the L-shaped portion may include a first selection gate linear region SG1_{H} that extends in the X direction and a first selection gate end region SG1_{V} that extends from the first selection gate linear region SG1_{H} in the −Y direction. The L-shaped portion may also include a first selection gate first edge SG1_{E1} that is adjacent to the first memory block MB1, a first selection gate second edge SG1_{E2} that is adjacent to the inter-SG dividing region 10, a first selection gate third edge SG1_{E3} that is adjacent to the second memory block MB2, a first selection gate fourth edge SG1_{E4} that is adjacent to the contact formation region C3, and a first selection gate fifth edge SG1_{E5} that is adjacent to an edge of the inter-SG dividing region 10 (e.g., edge extending in the Y direction). The first selection gate end region SG1_{V} may include a region of the L-shaped portion that is disposed below the first selection gate second edge SG1_{E2} and is at least partially bounded by the first selection gate fourth edge SG1_{E4} and the first selection gate third edge SG1_{E3} and the first selection gate fifth edge SG1_{E5}. In other words, for example, if the first selection gate linear region SG1_{H} extends in the X direction to the right end in the figure (e.g., to the first selection gate fourth edge SG1_{E4}) then the first selection gate end region SG1_{V} will extends from an end portion of the first selection gate linear region SG1_{H} in the −Y direction. The first selection gate linear region SG1_{H} is generally bounded in the Y direction by the first selection gate first edge SG1_{E1}, at least a portion of the first selection gate second edge SG1_{E2} and the boundary (not shown) formed between the first selection gate end region SG1_{V} and the first selection gate linear region SG1_{H}. In the Y direction, the word lines WL and dummy word lines DWL of the second memory block MB2 are included on the lower side of the second selection gate SG2. In addition, in this example, the second selection gate SG2 includes a substantially linear portion, and includes a contact formation region C2. As illustrated, the contact formation region C2 has a substantially linear portion that is disposed on the right end of the linear portion of the second selection gate SG2. The substantially L-shaped portion of the first selection gate SG1 and the substantially linear portion of the second selection gate SG2 are positioned adjacent to each other.

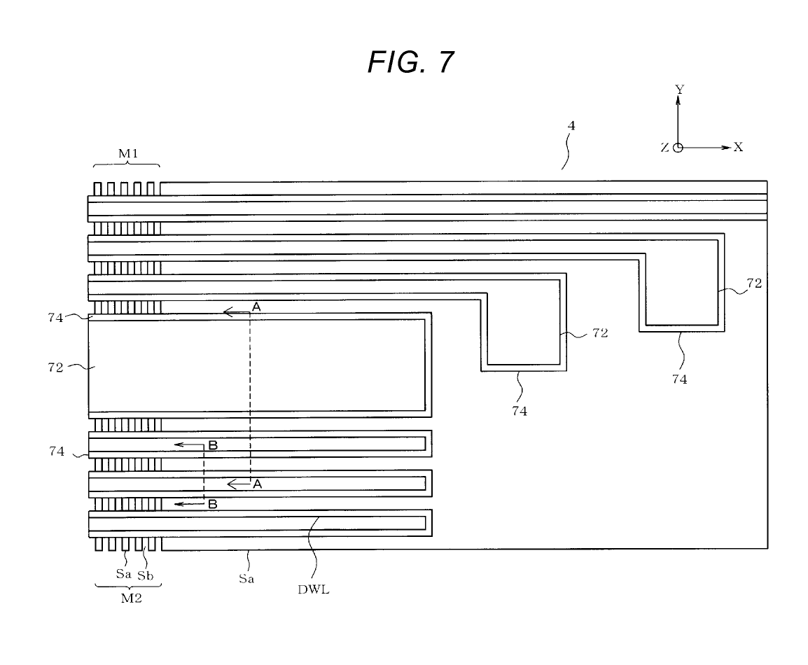

The dummy word lines DWL are folded back in a loop region 12 on the right end in the X direction, and thus are formed in a loop shape. When considering a first word line dividing region 14, the dummy word lines DWL can be seen as a half-loop shape. This is because a pattern is formed by a side wall 74 (FIG. 7) which is formed on a side wall of a mandrel 72 (FIG. 7) in the manufacturing step, as will be described later. The word lines WL and the dummy word lines DWL are divided into left and right in the figure by the first word line dividing region 14. Since the dummy word lines DWL are electrically disconnected due to the creation of the first word line dividing region 14 and become a portion which does not contribute to the operation, and thus they are referred to as the dummy word lines DWL herein.

The first word line dividing region 14 comes in contact with the lower end of the second selection gate SG2 in the Y direction. In the first word line dividing region 14, the word lines WL and the dummy word lines DWL are divided by removing a memory gate electrode MG which configures the word lines WL and the dummy word lines DWL. In the portion which comes in contact with the first word line dividing region 14, the electrode configuring the part of the lower end of the second selection gate SG2 in the Y direction may be removed.

The word lines WL of the first memory block MB1 are disposed to be adjacent to each other, on the upper side of the first selection gate SG1 in the Y direction. The word line WL is extracted to the extraction portion 4 on the right side in the X direction and is connected to a contact formation region C3. A contact 52 is formed in the vicinity of the center portion on the contact formation regions C1, C2, and C3, and a wire 54 is connected to the upper portion thereof.

In the Y direction, a distance W1 from the upper end of the contact formation region C1 in the figure (e.g., first selection gate first edge SG1_{E1}) to the lower end thereof (e.g., first selection gate third edge SG1_{E3}) is substantially the same as a distance W2 from the upper end of the first selection gate SG1 (e.g., first selection gate first edge SG1_{E1}) to the lower end of the second selection gate SG2 (e.g., second selection gate first edge SG2_{E1}). That is, it can be said that, the distance W2 from the end portion of the first selection gate SG1 which does not face the second selection gate SG2 (e.g., first selection gate first edge SG1_{E1}) to the end portion of the second selection gate SG2 which does not face the first selection gate SG1 (e.g., second selection gate first edge SG2_{E1}) is equivalent to a width (distance W1) of the contact formation region C1 in the Y direction in the figure. In the Y direction, a distance W3 from the upper end of the contact 52 of the contact formation region C1 to the upper end of the contact formation region C1 (e.g., first selection gate first edge SG1_{E1}) is larger than a distance W4 from the lower end of the contact 52 of the contact formation region C2 to the lower end of the contact formation region C2 (e.g., second selection gate first edge SG2_{E1}). In one configuration, the distance W3 is greater than the width W_{SG1} (e.g., measured in the Y direction) of the first selection gate linear region SG1_{H} of the first selection gate SG1 that extends in the X direction. In this case, if the first selection gate linear region SG1_{H} is said to extend in the X direction to the right end in the figure (e.g., to the first selection gate fourth edge SG1_{E4}) and the first selection gate end region SG1_{V} extends from the first selection gate linear region SG1_{H} in the −Y direction, then the contact 52 can be said to be disposed within the first selection gate end region SG1_{V}.

In addition, the first word line dividing region 14 is formed between the contact 52 of the contact formation region C2 and the memory cell region M2 in the X direction. It can be said that, the first word line dividing region 14 is disposed on the memory cell region M2 side with respect to the contact 52.

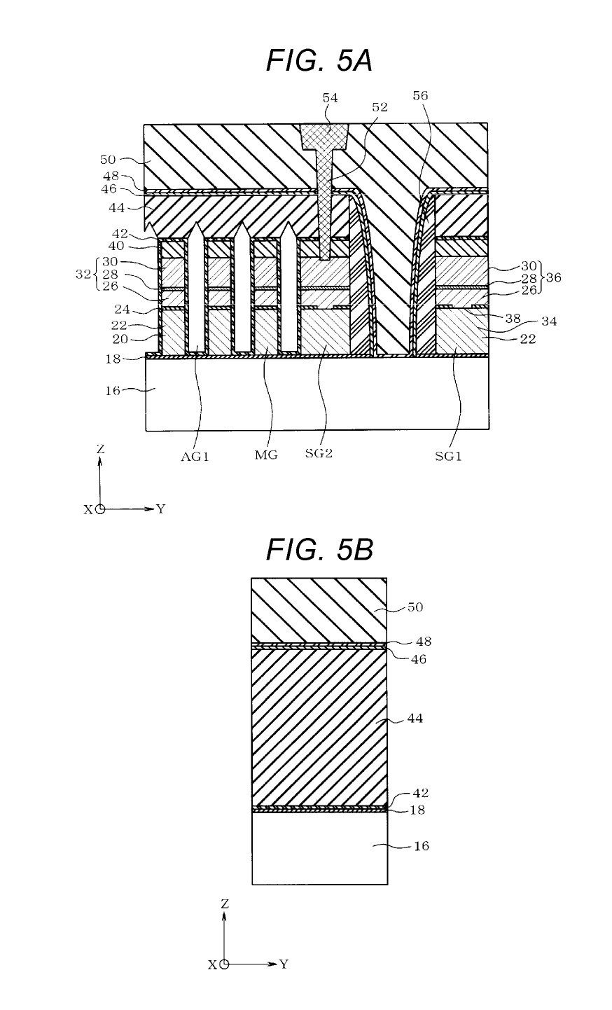

FIG. 5A is an example of a longitudinal or side cross-sectional view showing a structure formed by viewing the structure at section line A-A in FIG. 4. FIG. 5A shows an example of a longitudinal cross-sectional view of a part from the dummy word lines DWL of the second memory block MB2 to the second selection gate SG2 and the first selection gate SG1. A gate insulating film 18 is formed above a semiconductor substrate 16, and has a charge storage layer 20, an interelectrode insulating film 24, a control gate electrode 32 and a first insulating film 40 that are laminated and formed thereon, and accordingly a memory gate electrode MG (word line WL and the dummy word line DWL) is configured thereon.

The charge storage layer 20 includes a first polysilicon film 22 (polysilicon). The interelectrode insulating film 24 includes an oxide nitride oxide (ONO) film, which is formed by a stack of a silicon oxide film/silicon nitride film/silicon oxide film, for example. The control gate electrode 32 includes a second polysilicon film 26 (polysilicon), a barrier metal 28, and a metal film 30, which are formed in a stacked configuration. The barrier metal 28 may be formed with tungsten nitride (WN), for example. The metal film 30 may be formed with tungsten (W), for example. The first insulating film 40 may be formed with a silicon nitride film, for example.

For the charge storage layer 20, a laminated film of an insulating film with a trap level or an insulating film with polysilicon and a trap level can be used.

In addition, a lower electrode layer 34, an inter-electrode insulating film 24, an upper electrode layer 36 and the first insulating film 40 are formed above the semiconductor substrate 16, and accordingly the first selection gate SG1 and the second selection gate SG2 are formed. The lower electrode layer 34 may be formed with a first polysilicon film 22. The upper electrode layer 36 includes the second polysilicon film 26, the barrier metal 28, and the metal film 30. An opening portion 38 is formed in the inter-electrode insulating film 24, and the lower electrode layer 34 and the upper electrode layer 36 come in contact with each other via the opening portion 38.

Side wall insulating films 56 are formed between the first selection gate SG1 and the second selection gate SG2 which is on the side surfaces of the first selection gate SG1 and the second selection gate SG2. A fourth insulating film 46, a fifth insulating film 48, and an interlayer insulating film 50 are provided on the upper portion thereof. A void (cavity) is formed between the memory gate electrodes MG to form a first air gap AG1. The memory cell regions M1 and M2 also have the same structure, and the first air gap AG1 is also formed between the memory gate electrodes MG configuring the word lines WL or the dummy word lines DWL. With the first air gap AG1, parasitic capacitance between memory gate electrodes MG adjacent to each other is decreased, and interference between the memory cells can be decreased.

The contact 52 is connected to the upper portion of the upper electrode layer 36 of the second selection gate SG2 by penetrating from the interlayer insulating film 50 to the first insulating film 40, and the wire 54 is provided on the contact 52. In one embodiment, as will be described later, the wire 54 and the contact 52 are formed using a so-called dual damascene process, and accordingly they are integrally configured.

FIG. 5B is an example of a longitudinal or side cross-sectional view showing a structure of the first word line dividing region 14, and is an example of a longitudinal cross-sectional view illustrating a structure taken along section line B-B of FIG. 4. The gate insulating film 18, a second insulating film 42, a third insulating film 44, the fourth insulating film 46, the fifth insulating film 48, and the interlayer insulating film 50 are formed in this order and provided on the semiconductor substrate 16. In this region, the memory gate electrodes MG that would be used to form the word line WL or the dummy word line DWL have been removed, and the entire surface of the semiconductor substrate 16 is buried with the various insulating films, which include the gate insulating film and the second to fifth insulating films. That is, the first air gap AG1 is not formed in the first word line dividing region 14. That is, the first air gap AG1 in a region in which the memory cell region MA and the dummy word line DWL are formed is divided by the first word line dividing region 14. The open portion of the first air gap AG1 is blocked by the first word line dividing region 14.

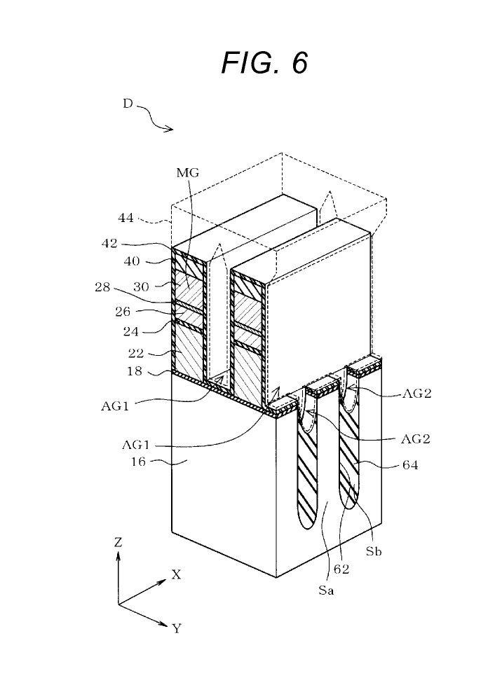

FIG. 6 is an example of a perspective view showing a stereoscopic structure of a region D of the memory cell region M2 of FIG. 4. The memory gate electrode MG is formed above the semiconductor substrate 16. The film configuration of the memory gate electrode MG is as described above. The first air gap AG1 is formed between the memory gate electrodes MG, and the third insulating film 44 covers so as to bridge over the memory gate electrode MG on the upper portion thereof. The first air gap AG1 is a void formed on the memory gate electrode MG and the third insulating film 44, and extends in the X direction in the figure.

The element isolation areas Sb are provided on the semiconductor substrate 16 and an element isolation groove 62 is formed on the element isolation area Sb. The element region Sa is formed between the element isolation areas Sb. An element isolation insulating film 64 is buried in the element isolation groove 62. The element isolation insulating film 64 is formed with a silicon oxide film, for example. The upper portion of the element isolation insulating film 64 is partially removed to be a void, and a second air gap AG2 is formed. The second air gap AG2 is formed so as to go through the lower portion of memory gate electrode MG, and extends in the Y direction in FIG. 6.

In the lower portion of the memory gate electrode MG, the memory gate electrode MG covers the upper portion of the second air gap AG2, and the first air gap AG1 and the second air gap AG2 are connected to each other on both sides of the memory gate electrode MG. The memory cell region M1 also has the same structure, and the second air gap AG2 is formed on the element isolation groove 62 including the portion directly below the memory gate electrode MG.

The first word line dividing region 14 may be formed on the element isolation insulating film 64. In this case, a width of the first word line dividing region 14 in the X direction is preferably greater than a width of the element isolation insulating film 64. As a result, the second air gap AG2 can be buried by the third insulating film 44 with the first air gap AG1. Accordingly, the first air gap AG1 and the second air gap AG2 can be blocked in the boundary with the first word line dividing region 14.

As described above, by using the layout in which the contact formation region C1 can be formed to be large, the distance W3 from the contact 52 to the end portion (upper end portion) of the contact formation region C1 can be set to be greater in the Y direction. Accordingly, as will be described later, in a cleaning process which is performed in an opening step of the contact 52 (FIGS. 4 and 5A), it is possible to prevent a chemical solution from reaching the air gap structures A1 between the first memory block MB1 that are formed at the end portion (upper end portion of the contact formation region C1 in the Y direction in the figure) of the contact formation region C1 and the first selection gate SG1, due to the invasion of a chemical solution used in a cleaning process preformed on the contact 52 of the first selection gate SG1.

Accordingly, it is possible to prevent the chemical solution from passing through voids of the first air gap AG1 and the second air gap AG2 of the memory cell region M1 and attacking the memory gate electrode MG found in the memory cell region M1. That is, by securing the distance from the contact 52 to the first air gap AG1, it is possible to suppress invasion of the chemical solution into the first air gap AG1 through the contact formation region C1, and possible to significantly decrease a proportion of defects that would have been created, due to the chemical attack of these structures. It is considered that the chemical solution which invades from the opening portion of the contact 52 approaches the end portion of the contact formation region C1 through the grain boundary of the metallic material (for example, tungsten) configuring the contact formation region C1 and invades the first air gap AG1.

By disposing the first word line dividing region 14 between the contact 52 of the contact formation region C2 and the memory cell region M2, the following effects can be exhibited. That is, during the cleaning process performed after the opening step of the contact 52, it is possible to prevent (shield) the chemical solution from reaching the memory cell region M2 by entering from the opening portion of the contact 52 and passing through the first air gap AG1, which is adjacent to the contact formation region C2, via the contact formation region C2. Accordingly, it is possible to prevent the dissolution of portions of the memory gate electrode MG of the memory cell region M2.

As described above, by preventing the chemical solution from dissolving portions of the memory gate electrode MG of the memory cell region M2, it is possible to prevent damage to the memory gate electrode MG, due to the removal of the memory gate electrode MG material. In addition, the metal material dissolved in the chemical solution can also tend deposit in the first air gap AG1 and the second air gap AG2, and accordingly it is possible to prevent shorting of the adjacent memory gate electrode MG by use of one or more of the embodiments disclosed herein. Further, it is possible to provide a nonvolatile semiconductor memory device having high reliability and device yield. Since the memory cell which stores data is not connected to the dummy word lines, even though the dummy word lines DWL may be attacked during the cleaning process, the reliability of the nonvolatile semiconductor memory device is unlikely to be decreased.

Manufacturing Method

Next, a manufacturing method of the nonvolatile semiconductor memory device according to the first embodiment will be described with reference to FIGS. 4 to 26B. FIGS. 4, 7, 9, 11, 13, 15, 17, 19, 21, 23, and 25 are examples of a plan view showing a layout of the NAND-type flash memory device according to the first embodiment, and are examples of an enlarged plan view of the first end portion T1 shown in FIG. 3B. FIGS. 5A, 8A, 10A, 12A, 14A, 16A, 18A, 20A, 22A, 24A, and 26A are examples of a longitudinal cross-sectional view showing a structure taken along section line A-A of FIGS. 4, 7, 9, 11, 13, 15, 17, 19, 21, 23, and 25, and show examples of a cross-sectioned structure from the memory gate electrode MG to the first selection gate SG1. FIGS. 5B, 8B, 10B, 12B, 14B, 16B, 18B, 20B, 22B, 24B, and 26B are examples of a longitudinal cross-sectional view showing a structure taken along section line B-B of FIGS. 4, 7, 9, 11, 13, 15, 17, 19, 21, 23, and 25, and show a structure of the first word line dividing region 14. An example of a process of forming a NAND-type flash memory device 1 as a nonvolatile semiconductor memory device is described below.

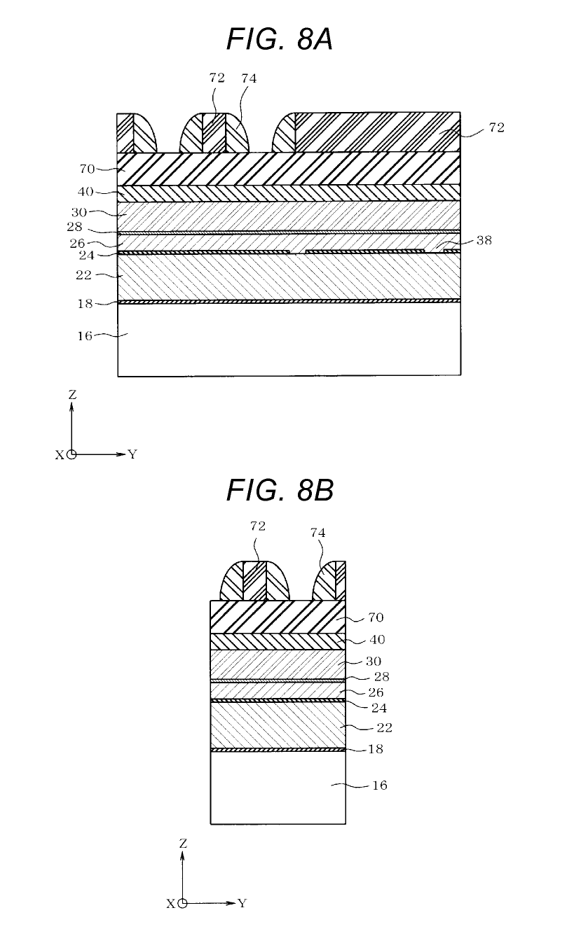

First, as shown in FIGS. 7 and 8A and 8B, the gate insulating film 18, the first polysilicon film 22, the interelectrode insulating film 24, the second polysilicon film 26, the barrier metal 28, the metal film 30, and the first insulating film 40 are formed on the semiconductor substrate 16. Although not shown in the cross-sectional views shown in these figures, the element isolation area Sb is formed on the semiconductor substrate 16.

A silicon substrate can be used as the semiconductor substrate 16, for example. A silicon on insulator (SOI) substrate may also be used instead of the silicon substrate, for example. A silicon oxide film can be used as the gate insulating film 18. The gate insulating film 18 can be formed by performing thermal oxidation of the semiconductor substrate 16 in a dry O₂ atmosphere, at a temperature of approximately from 750° C. to 1000° C., for example. An oxynitride film may also be formed as the gate insulating film 18, instead of the silicon oxide film. A polysilicon film which is formed by a chemical vapor deposition (CVD) method and can be used as the first polysilicon film 22, for example.

An ONO film which is formed by the CVD method can be used as the interelectrode insulating film 24, for example. In the formation portion of the first selection gate SG1 and the second selection gate SG2, the opening portion 38 is formed on the interelectrode insulating film 24. The opening portion 38 is formed using a lithography method and a reactive ion etching (RIE) method. A polysilicon film which is formed by the CVD method can be used as the second polysilicon film 26, for example. Tungsten nitride, which is formed by a sputtering method, can be used to form the barrier metal 28, for example. Tungsten, which is formed by the sputtering method, can be used to form the metal film 30, for example. A silicon nitride film which is formed by the CVD method can be used to form the first insulating film 40, for example.

Next, a hard mask layer 70 and a mandrel 72 are formed, and the mandrel 72 is patterned using lithography and RIE methods. Then, the side wall 74 is formed to be conformal by use of a CVD method, for example. The conformal film is then etched back by use of an anisotropic RIE method to form the side wall 74 on a side wall portion of the mandrel 72. A width of the side wall 74 can be adjusted depending on the thickness of the deposited conformal film, which becomes the side wall 74. For the hard mask layer 70, the mandrel 72, and the side wall 74, suitable combinations may be formed from a silicon oxide film, a silicon nitride film, a carbon film, a polysilicon film, and/or the like, for example.

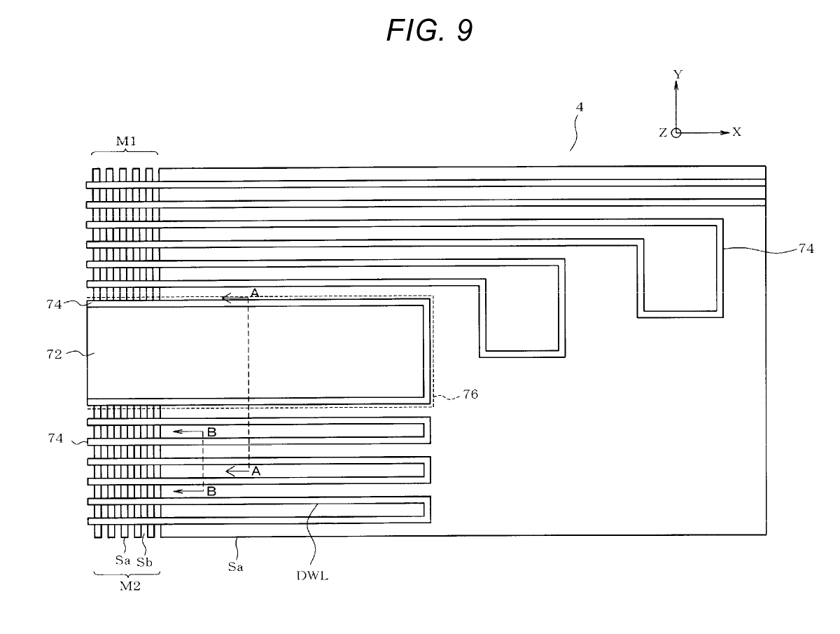

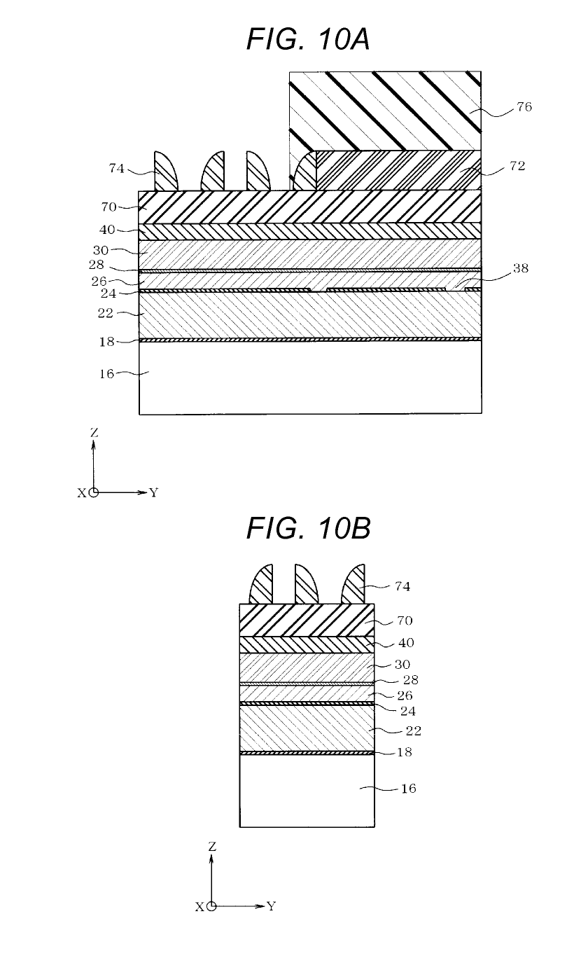

Next, as shown in FIGS. 9 and 10A and 10B, a resist 76 is formed so as to cover at least the regions of the first selection gate SG1 and the second selection gate SG2 that is to be formed. Then, the mandrel 72 is selectively removed by etching. The etching process may include a dry etching or wet etching process. The mandrel 72 in the region covered by the resist 76 is not removed and remains.

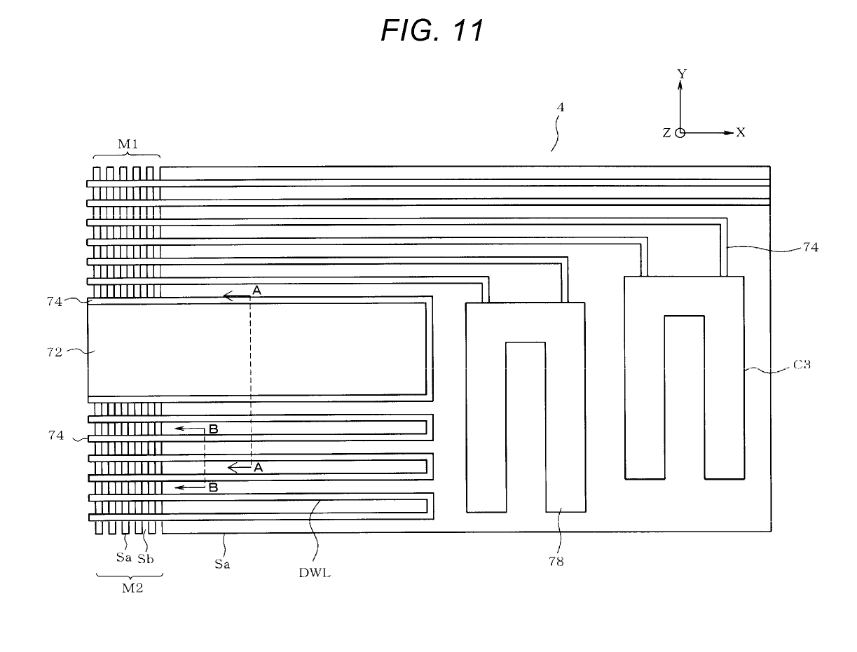

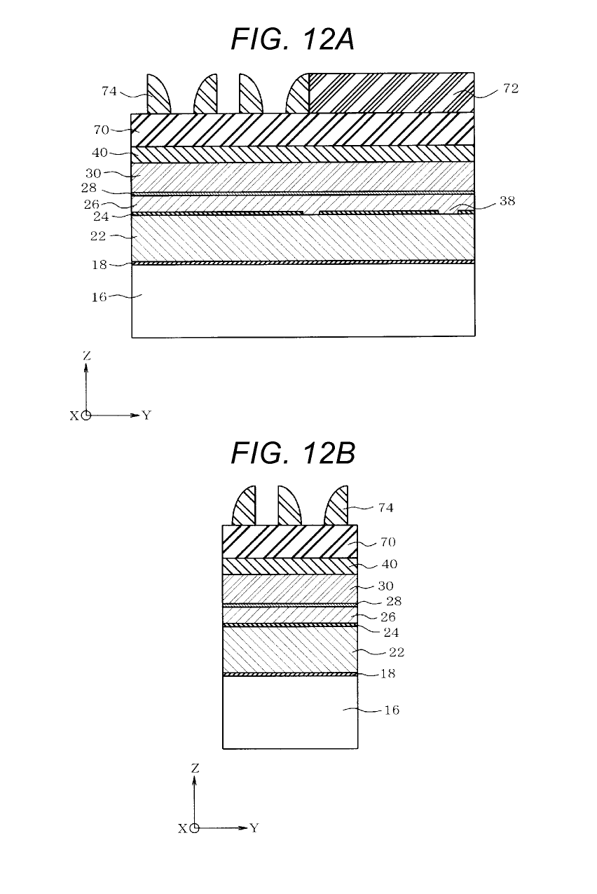

Next, as shown in FIGS. 11 and 12A and 12B, the resist 76 is removed. The removal of the resist 76 can be performed by an ashing process performed using an oxygen plasma, for example. Then, a resist 78 is formed as a mask on the portion of the contact formation region C1 connected to the extraction portion 4. At that time, the resist 78 may be an approximate U shape which connects two contact formation regions C3 adjacent to each other in the Y direction.

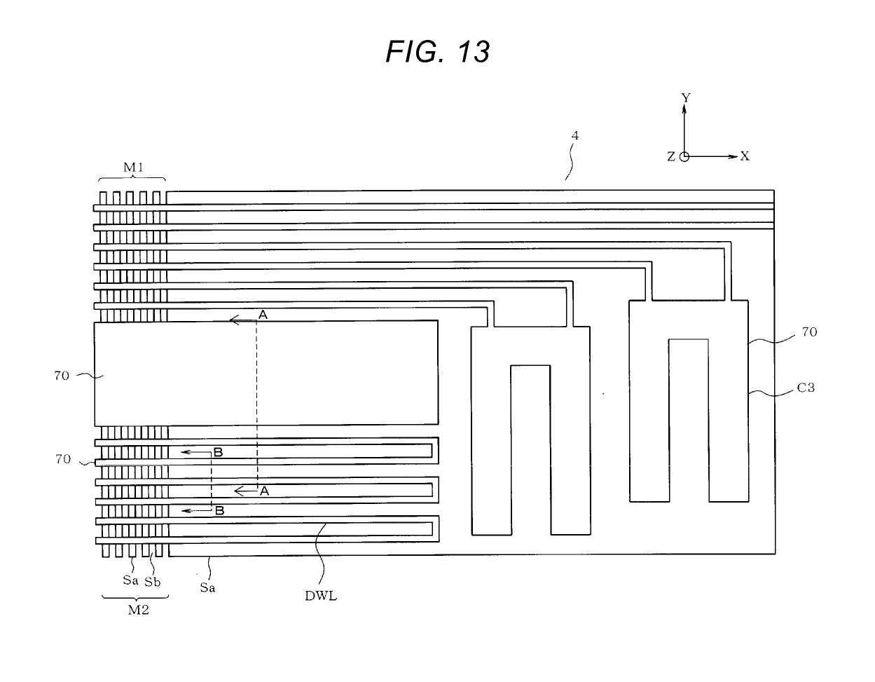

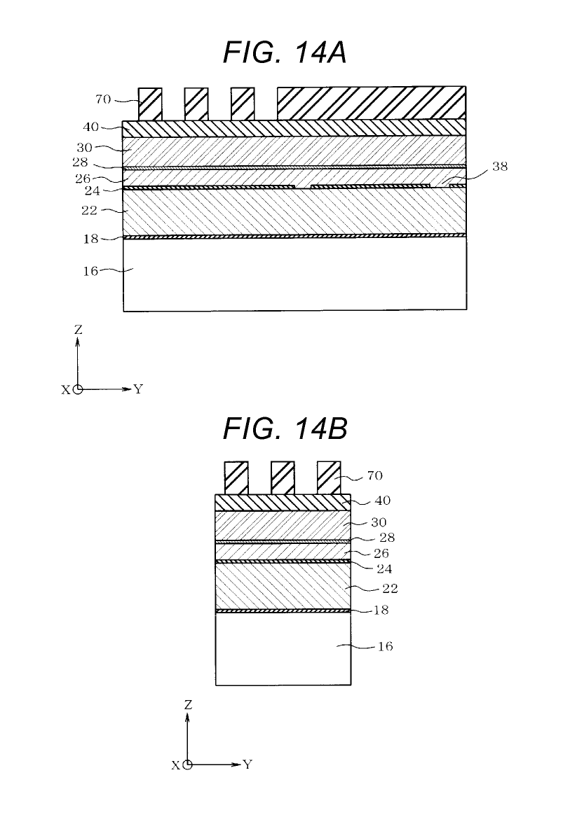

Next, as shown in FIGS. 13 and 14A and 14B, an etching process is performed using an RIE method using the mandrel 72, the side wall 74, and the resist 78 as the mask, and the hard mask layer 70 is etched. In the etching process, anisotropic conditions are used, and the first insulating film 40 is used as an etching stop. Then, as shown in FIGS. 14A-14B, the mandrel 72, the side wall 74, and the resist 78 are removed. By performing this step, the pattern which is formed by the mandrel 72, the side wall 74, and the resist 78 is transferred to the hard mask layer 70.

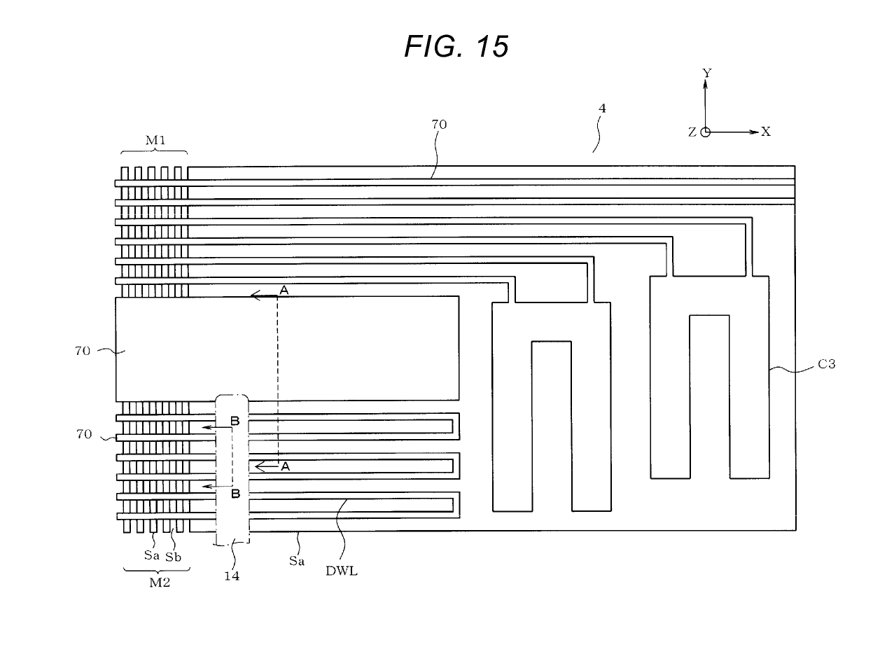

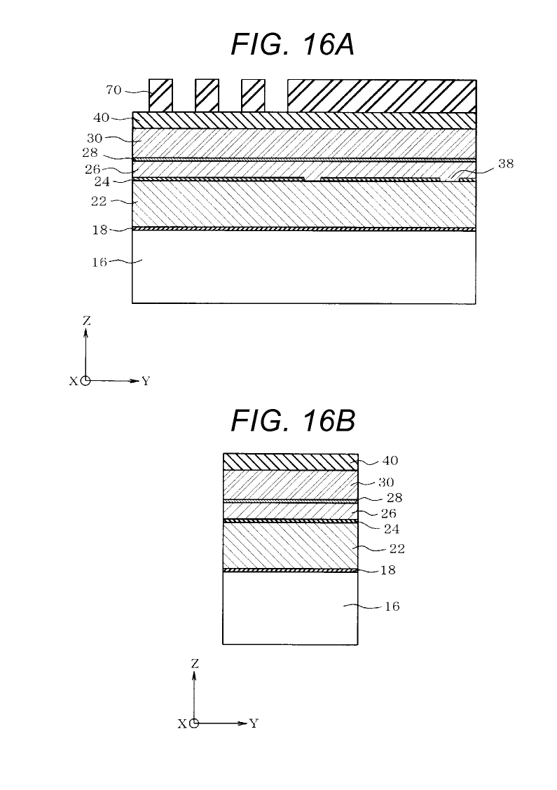

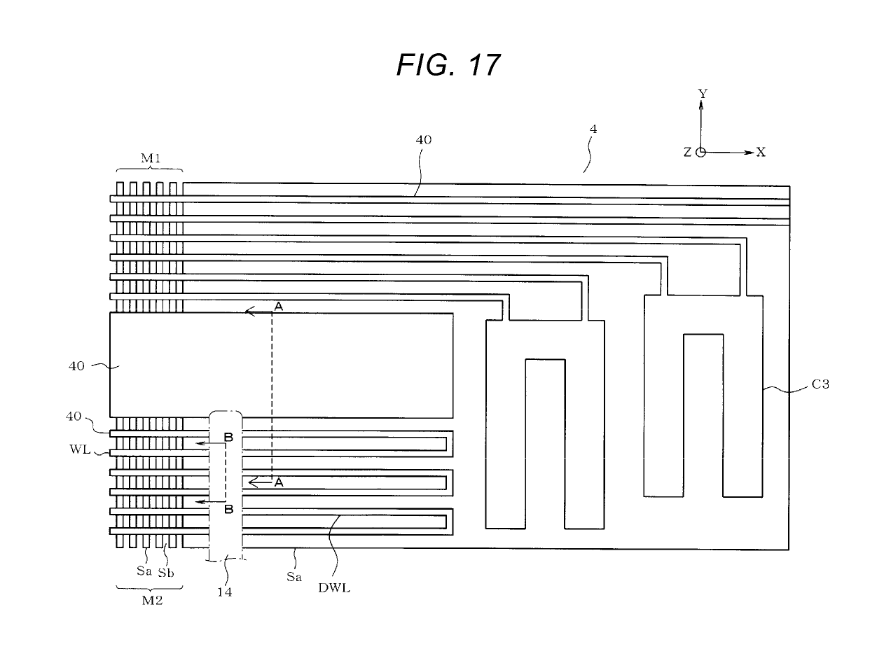

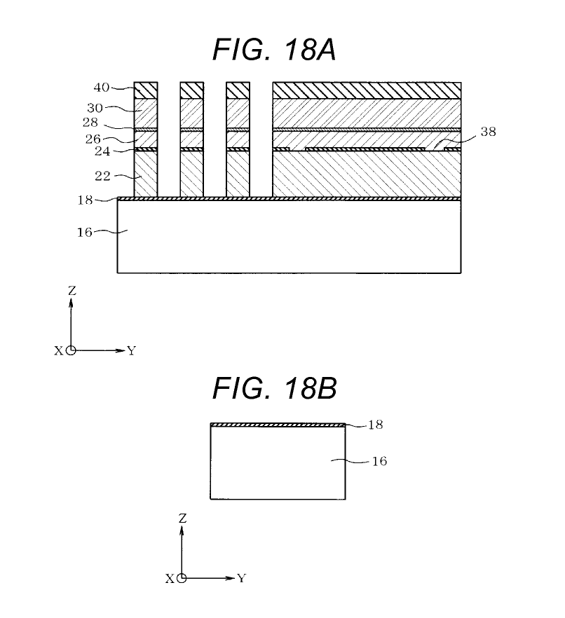

Next, as shown in FIGS. 15 and 16A and 16B, the hard mask layer 70 of the first word line dividing region 14 is removed using a lithography method and an RIE method. Then, as shown in FIGS. 17 and 18A and 18B, an etching process is performed by an RIE method using the hard mask layer 70 as a mask. The etching process may be performed using anisotropic conditions. In the etching, the first insulating film 40, the metal film 30, the barrier metal 28, the second polysilicon film 26, the inter-electrode insulating film 24, and the first polysilicon film 22 are etched in this order, and the etching process is stopped on the upper portion of the gate insulating film 18. Since the hard mask layer 70 was removed in the first word line dividing region 14 shown in FIG. 18B, a state in which the portion from the first insulating film 40 to the first polysilicon film 22 is removed and the gate insulating film 18 is formed on the semiconductor substrate 16, is shown. Then, the hard mask layer 70 on the entire surface is removed. The hard mask layer 70 may be removed at the time of the etching described above, in some cases.

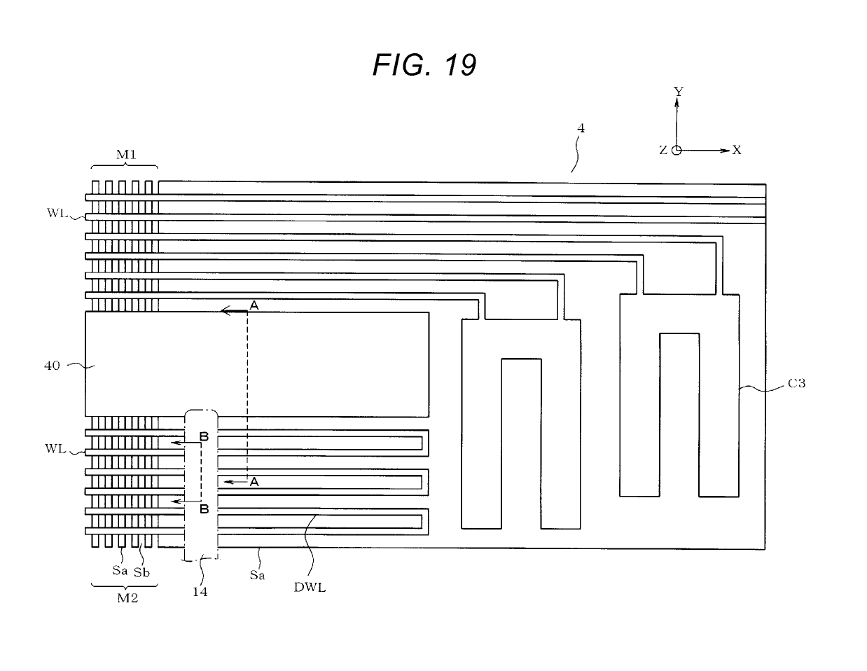

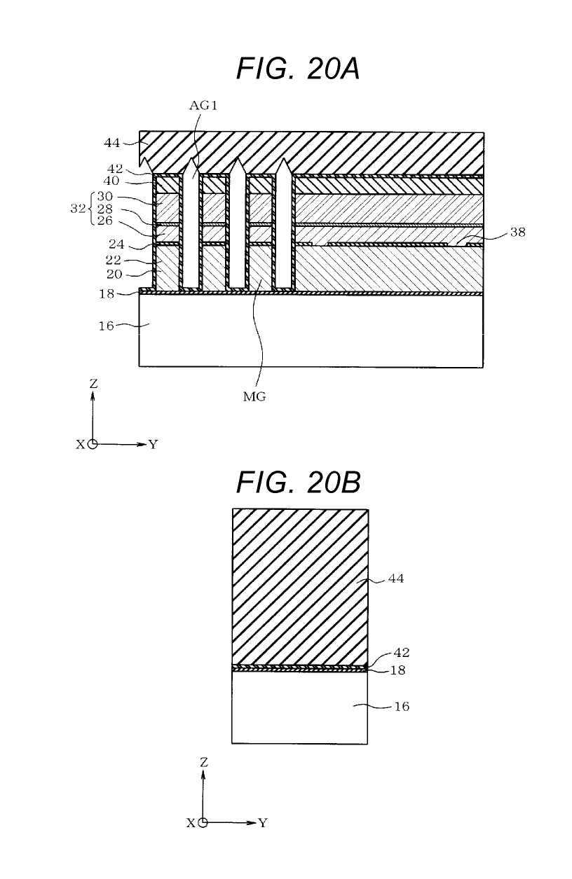

Next, as shown in FIGS. 19 and 20A and 20B, the second insulating film 42 and the third insulating film 44 are formed. The second insulating film 42, may comprise a silicon oxide film that is formed by a CVD method, for example. The second insulating film 42 is formed using a conformal deposition process. The second insulating film 42 is typically a relatively thin conformal layer. The third insulating film 44 may include a silicon oxide film that is formed using conditions that have a low burying property (low coating property) by use of a plasma CVD method, for example.

Accordingly, the third insulating film 44 cannot enter the void formed between the memory gate electrodes MG having a narrow spacing, and the third insulating film 44 is formed so as to cover the upper surface of the memory gate electrodes MG. The upper portion of the void formed between the memory gate electrodes MG is blocked by the third insulating film 44 and the first air gap AG1 is formed. The word line WL and the dummy word line DWL are formed by the memory gate electrode MG. Accordingly, the first air gap AG1 is formed between the word lines WL and between the dummy word lines DWL having narrow intervals.

Since the third insulating film 44 enters regions between the memory gate electrodes MG that have a wide spacing, interval or a region in which patterns are sparsely disposed, these regions will be buried with the third insulating film 44, and thus the first air gap AG1 is not formed in these areas. For example, the first air gap AG1 is not formed in the region in the vicinity of the contact formation region C3 in FIG. 19. In the portions in which the narrow interval between the memory gate electrodes MG transitions to wide intervals, the first air gap AG1 will be blocked in the portion where the spacing is wide. In FIG. 19, the third insulating film 44 is not shown. As shown in FIG. 20B, the first word line dividing region 14 is covered and buried by the second insulating film 42 and the third insulating film 44.

In addition, although not shown in FIGS. 20A and 20B, a part of the upper portion of the element isolation area Sb including the portion directly below the memory gate electrode MG is etched and removed, before the formation of the second insulating film 42. This etching may be performed using a chemical solution containing diluted hydrofluoric acid, for example. Accordingly, the second air gap AG2 described in FIG. 6 is formed.

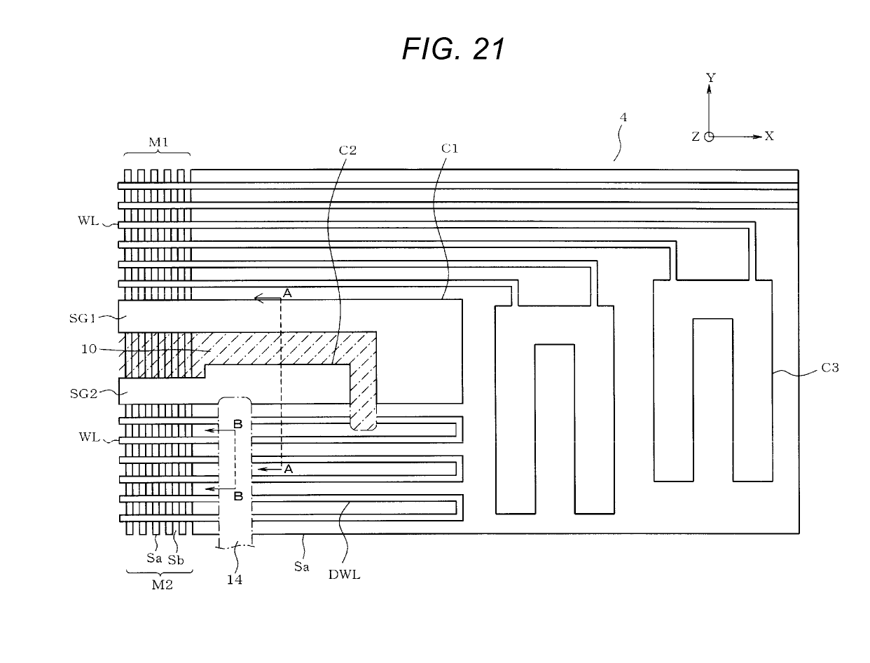

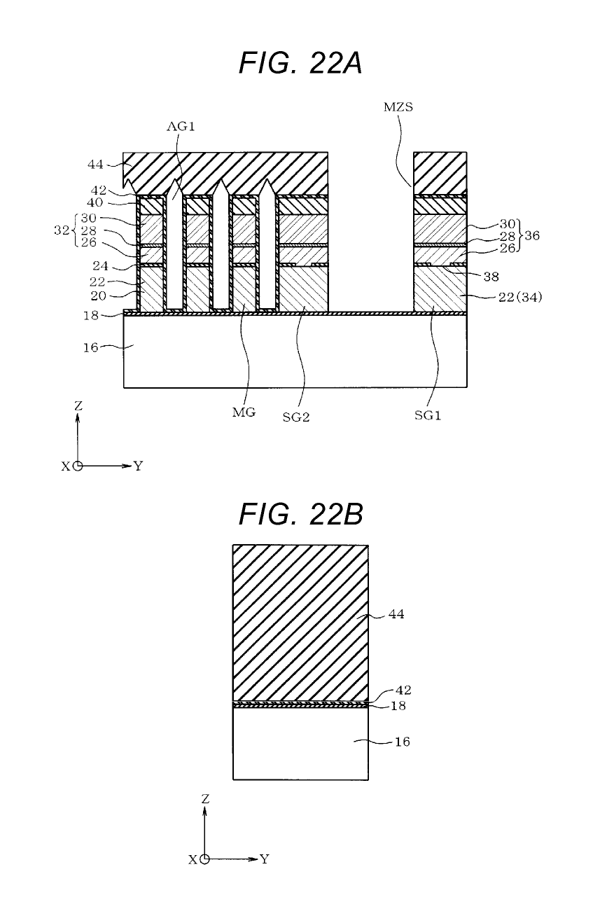

Next, as shown in FIGS. 21 and 22A and 22B, the inter-SG dividing region 10 is formed using an etching process using a lithography method and an RIE method. The anisotropic etching process is performed to cause at least a portion of the third insulating film 44, the second insulating film 42, the metal film 30, the barrier metal 28, the second polysilicon film 26, the interelectrode insulating film 24, and the first polysilicon film 22 in the inter-SG dividing region 10 to be etched and removed in that order. By performing this etching step, the first selection gate SG1 and the second selection gate SG2 are formed. The inter-SG dividing region 10 shown in FIG. 21 extends to the right in the figure and is formed in a substantially L shape.

Accordingly, the second selection gate SG2 is formed in a linear shape that is shorter than the first selection gate SG1 in the Y direction. The first selection gate SG1 extends to the right in FIG. 21, and has a greater line width at the end portion, and is formed in a substantially L shape. For securing alignment margins in the lithography, the inter-SG dividing region 10 may extend in the Y direction to one or more dummy word lines DWL. FIG. 21 shows an example in which the inter-SG dividing region 10 extends to the first dummy word line DWL.

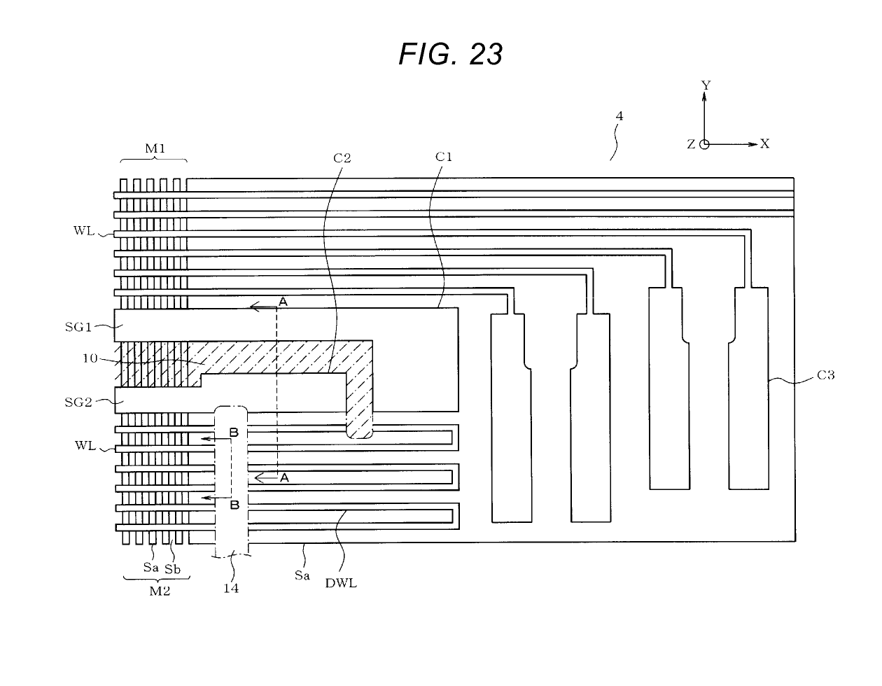

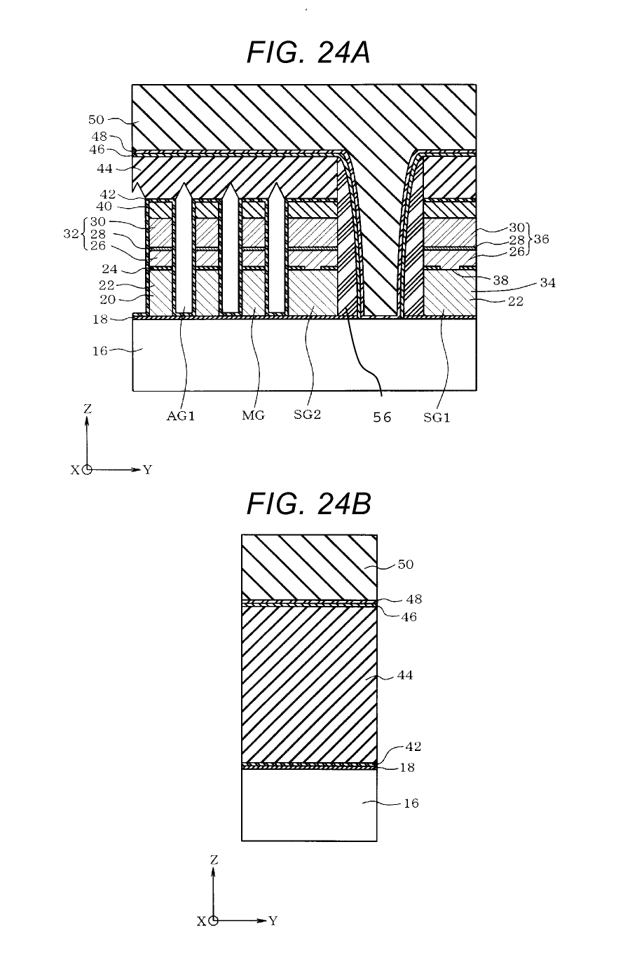

Next, as shown in FIGS. 23 and 24A and 24B, the side wall insulating films 56 are formed on the side walls of the first selection gate SG1 and the second selection gate SG2 of the inter-SG dividing region 10, and then the fourth insulating film 46, the fifth insulating film 48, and the interlayer insulating film 50 are formed. After that, a surface thereof is polished by a chemical mechanical polishing (CMP) method. The side wall insulating film 56 can be formed by forming a silicon oxide film using a CVD method, for example, and then performing an anisotropic etch back process across the entire surface by use of an RIE method.

A silicon oxide film which is formed by a CVD method can be used to form the fourth insulating film 46, for example. A silicon nitride film which is formed by a CVD method can be used to form the fifth insulating film 48, for example. A silicon oxide film which is formed by a CVD method using tetraethylorthosilicate (TEOS) as source gas can be used to form the interlayer insulating film 50, for example. The process of dividing the contact formation region to form regions C3, which are adjacent to each other, may be performed before the formation of the side wall insulating film 56. Optionally, in some cases, it may also be desirable to remove portions of the contact formation region C3 in one or more lithography and etching steps to form two disconnected regions, as illustrated in FIG. 23.

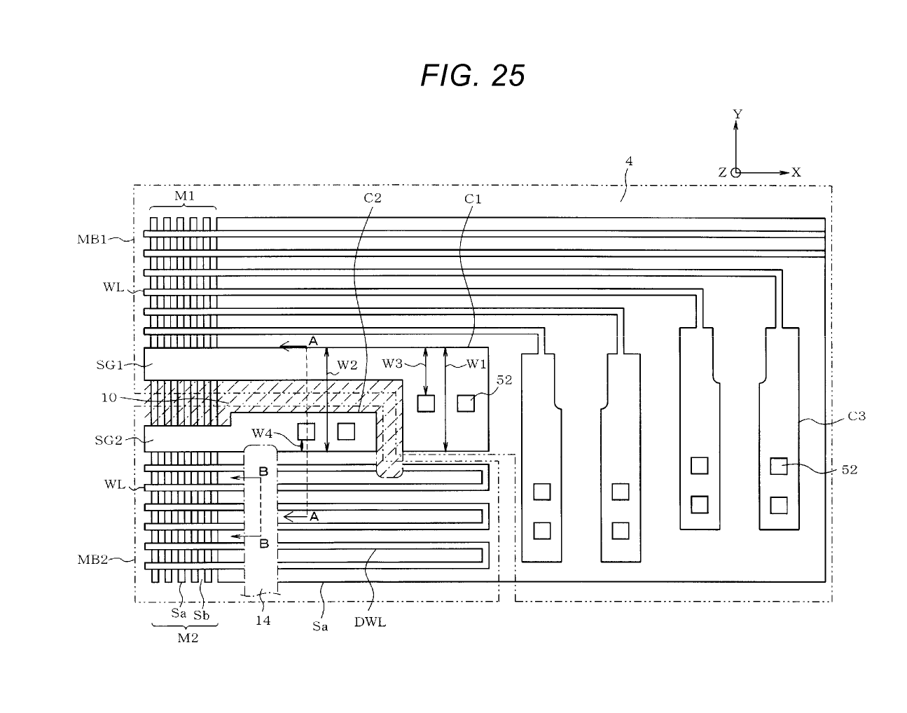

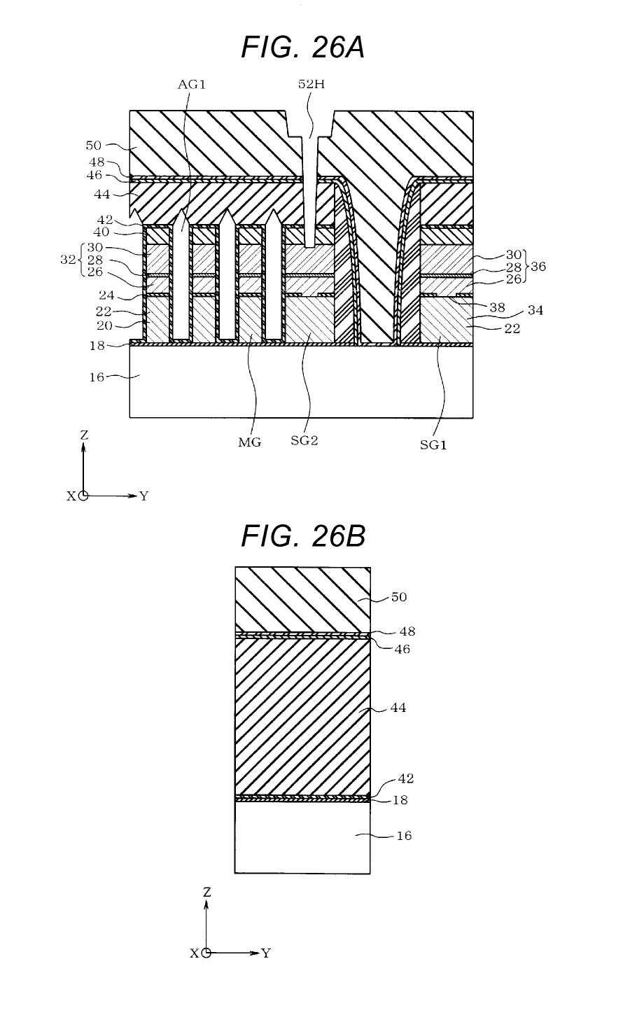

Next, as shown in FIGS. 25 and 26A and 26B, a contact hole 52H (FIG. 26A) is formed using a lithography method and an anisotropic RIE method. The contact hole 52H is formed so as to reach the metal film 30. After that, a groove of the wire 54 can also be formed by use of a dual damascene process. Then, a cleaning process is performed in order to clean the inside of the contact hole 52H. The cleaning is performed by use of a chemical solution, which typically includes an ammonia and a hydrogen peroxide solution, for example. This solution dissolves metals, such as tungsten for example.

In the contact formation region C2, the chemical solution may pass through the contact hole 52H formed in the contact formation region C2 and reach the first air gap AG1 formed between the dummy word lines DWL. The chemical solution may also pass through the grain boundary of a metal material (tungsten, for example) disposed in the contact formation region C2 and invade the end portion of the contact formation region C2. However, the chemical solution which reaches the first air gap AG1 is shielded by the first word line dividing region 14, and accordingly does not invade the memory cell region M2.

Accordingly, it is possible to avoid the attack and dissolution of portions of the memory gate electrode MG in the memory cell region M2 by the chemical solution or prevent the formation of a short between adjacent memory gate electrodes MG due to the redeposition of the metal etched away by the chemical solution. Therefore, the chemical solution, which is introduced into the first air gap AG1 and the second air gap AG2 in the memory cell region M2, is prevented from invading region 14.

If the first word line dividing region 14 did not exist, then when the chemical solution approaches the memory cell region M2 through the first air gap AG1, the chemical solution may invade the adjacent first air gap AG1 through the second air gap AG2 described above. Further, the chemical solution may invade a wider area of the memory cell region M2 through the second air gap AG2. When the chemical solution reaches the inside of the first air gap AG1, an opening in the word lines WL may be formed due to the dissolution of the tungsten film, from which the word lines WL is formed. In addition, a device malfunction, such as short or the like may form between the word lines WL, due to re-deposition of the dissolved tungsten in the first air gap AG1. When the number of malfunctioning regions is high, a defective chip is formed, and the device yield rate is decreased. In one embodiment, since it is possible to prevent the chemical solution from entering into the memory cell region M2 by the first word line dividing region 14, the problems described above will rarely occur.

Embodiments of the invention may also allow the distance W3 from the contact 52 (end portion of the contact hole 52H) to the end portion of the contact formation region C1 to be made a desirable size. Accordingly, the possibility that the chemical solution, which is used in a cleaning process, will reach the end portion of the contact formation region C1 is small, during the cleaning process time. Therefore, the possibility that the chemical solution will reach the first air gap AG1 between the word lines WL of the extraction portion 4 through the contact formation region C1 is small. In addition, the possibility that the chemical solution will reach the memory cell region M1 through the first air gap AG1 is small. Thus, it is possible to avoid the chemical attack of the memory gate electrode MG disposed in the word lines WL of the memory cell region M1 by the chemical solution and/or prevent the occurrence of a short between adjacent memory gate electrodes MG due to re-deposition of the metal removed by the chemical solution.

Next, as shown in FIGS. 4 and 5A and 5B, the grooves of the contact hole 52H and the wire 54 are buried with a conductive material. A barrier metal and a metal film are formed in the grooves to form the contact 52 and the wire 54. After that, a polishing process is performed by use of a CMP method, thus leaving the barrier metal and the metal film remain in the grooves. The contact 52 and the wire 54 are thus formed. A tungsten nitride film, which may be formed by the CVD method, can be used to form the barrier metal, for example. Tungsten, which may be formed by a CVD method, can be used to form the metal film, for example.

### Second Embodiment

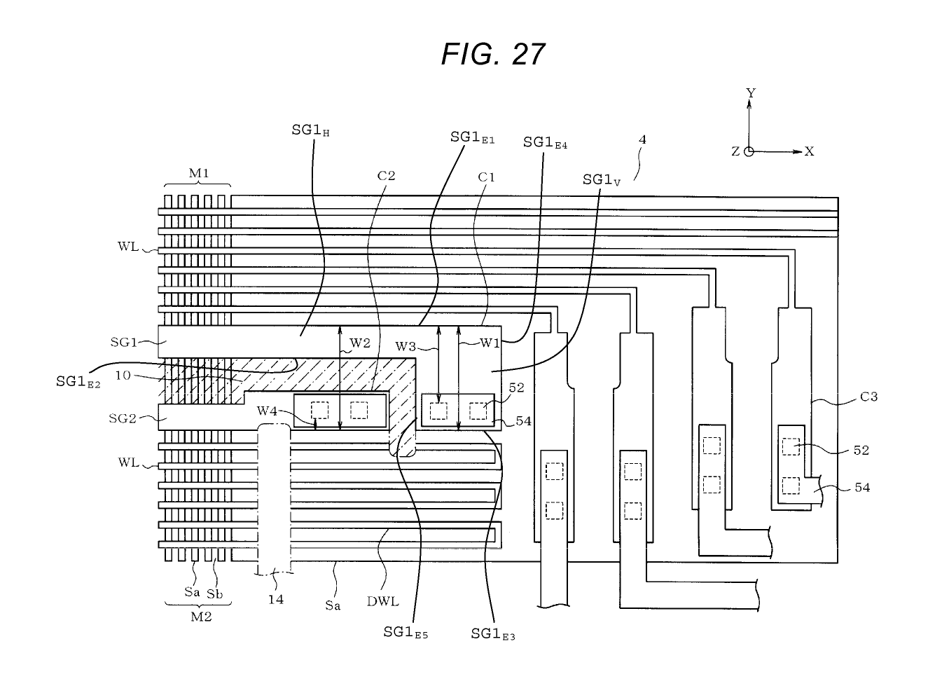

FIG. 27 is an example of a plan view showing a layout of the NAND-type flash memory device 1 according to a second embodiment. One aspect of the configuration illustrated in FIG. 27 that is different from the configurations discussed above, is a position of the contact 52. That is, the contact 52 is disposed in a position closer in the Y-direction to the lower end (dummy word line DWL side) of the contact formation region C1 (e.g., first selection gate third edge SG1_{E3}) than the upper end (e.g., first selection gate first edge SG1_{E1}). Accordingly, the distance W3 from the contact 52 to the upper end of the contact formation region C1 in the figure becomes larger, and it is possible to more effectively prevent the chemical solution from reaching the upper end of the contact formation region C1 (e.g., first selection gate first edge SG1_{E1}) through the contact 52 (contact hole 52H), and thus prevent the chemical solution from reaching the first air gap AG1 formed between the word lines WL of the extraction portion 4.

As discussed above, since the distance from the contact 52 to the dummy word line DWL side end portion (lower side of the contact 52 in the figure) becomes small, the chemical solution easily invades the first air gap AG1 on the dummy word line DWL side (lower side in the figure). However, since the invasion of the chemical solution into the memory cell region M2 is prevented by the first word line dividing region 14, it is possible to suppress the attack of the memory gate electrodes MG in the memory cell region M2 or the formation of a short or the like.

As described above, the position of the contact 52 may be changed so as to be closer to the lower end side (dummy word line DWL side) (e.g., first selection gate third edge SG1_{E3}) than the upper end side of the contact formation region C1 in the Y direction (e.g., first selection gate first edge SG1_{E1}). As a result, the distance W3 can be desirably large.

### Third Embodiment

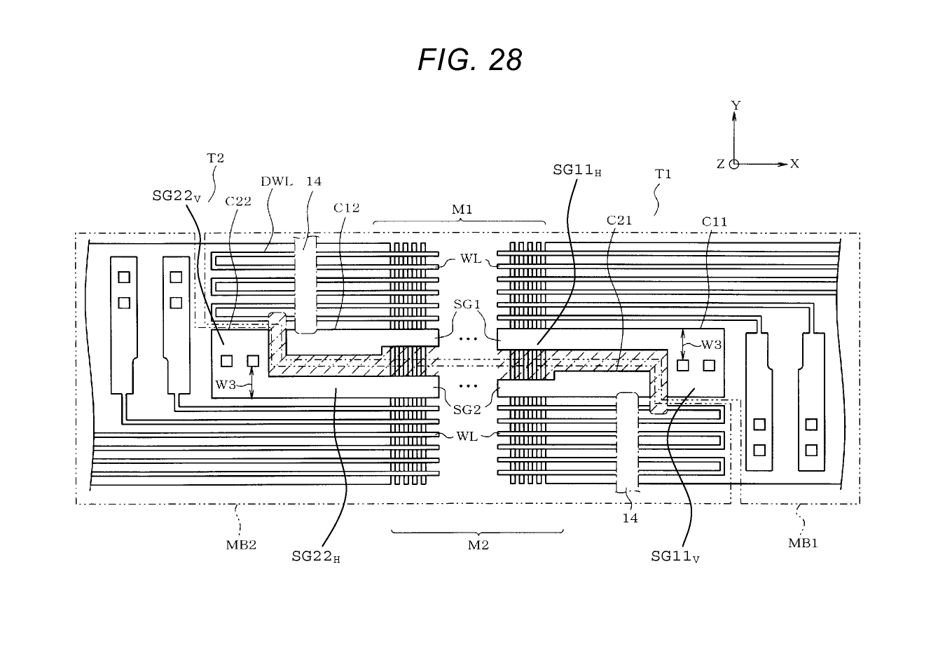

FIG. 28 is an example of a plan view showing a layout of the NAND-type flash memory device 1 according to a third embodiment. FIG. 28 includes an example of an enlarged plan view of the first end portion T1 and a second end portion T2 illustrated in FIG. 4. The first selection gate SG1 extends in the X direction in the figure, and includes a contact formation region C11 on the right end and a contact formation region C12 on the left end. The second selection gate SG2 extends in the X direction in the figure, and includes a contact formation region C21 on the right end and a contact formation region C22 on the left end.

The first selection gate SG1 and the second selection gate SG2 are separated from each other by the inter-SG dividing regions 10 which have a shape in which the substantially L-shaped portions are alternately connected to each other in an inverse orientation. The inter-SG dividing region 10 extends to the right side in the X direction between the first selection gate SG1 and the second selection gate SG2, and is folded down to the lower side in the Y direction in the vicinity of the end portion of the second selection gate SG2, and includes a substantially L-shaped portion. Accordingly, the contact formation region C21 includes a substantially linear portion, and the contact formation region C11 includes a substantially L-shaped portion which is folded to the lower side. As illustrated in FIG. 28, the L-shaped portion of the contact formation region C11 may include a first selection gate linear region SG11_{H} that extends in the X direction and a first selection gate end region SG11_{V} that extends from the first selection gate linear region SG11_{H} in the −Y direction. The substantially L-shaped portion of the contact formation region C11 and the substantially linear portion of the contact formation region C21 are adjacent to each other.

In addition, the inter-SG dividing region 10 extends to the left side in the X direction between the first selection gate SG1 and the second selection gate SG2, and is folded to the upper side in the Y direction in the vicinity of the end portion of the first selection gate SG1, and includes a substantially L-shaped portion. Accordingly, the contact formation region C12 includes a substantially linear portion, and the contact formation region C22 includes a substantially L-shaped portion, which is folded in an upward direction. As illustrated in FIG. 28, the L-shaped portion of the contact formation region C22 may include a second selection gate linear region SG22_{H} that extends in the X direction and a second selection gate end region SG22_{V} that extends from the second selection gate linear region SG22_{H} in the +Y direction. The substantially L-shaped portion of the contact formation region C22 and the substantially linear portion of the contact formation region C12 are adjacent to each other. As described above, the first selection gate SG1 and the second selection gate SG2 have a layout so as to be separated by the inter-SG dividing region 10, which has a shape that is substantially L-shaped in the Y direction at opposing ends. That is to say, in some configurations, the first selection gate SG1 and the second selection gate SG2 are formed so as to have a layout that is point symmetric, or in other words has point symmetry.

Herein, the contact 52 is not disposed in the contact formation regions C12 and C21. That is, in the first selection gate SG1, the contact 52 is disposed only in the contact formation region C11, and in the second selection gate SG2, the contact 52 is disposed only in the contact formation region C22. For example, as shown in FIG. 3B, it is an effective layout when the extraction portions 4 are alternately disposed on the right and left side in the X direction for each memory block MB.

With the layout described above, the effects of the first and second embodiments are obtained.

In a top view, the contact 52 is not disposed in the contact formation regions C12 and C21 having smaller areas than the areas of the contact formation regions C11 and C22. As a result, a probability of the chemical solution reaching the first air gap AG1 during the cleaning process is decreased.

In addition, by employing the layout described above, a degree of freedom of the layout of the first word line dividing region 14 is improved. That is, the contact 52 is not disposed in the contact formation regions C12 and C21. That is, the chemical solution will not reach the air gap structures through the contact formation regions C12 and C21. Accordingly, the first word line dividing region 14 may be formed between the contact formation region C11 and the memory cell region M2, and between the contact formation region C22 and the memory cell region M1, not depending on the contact formation regions C12 and C22.

### Fourth Embodiment

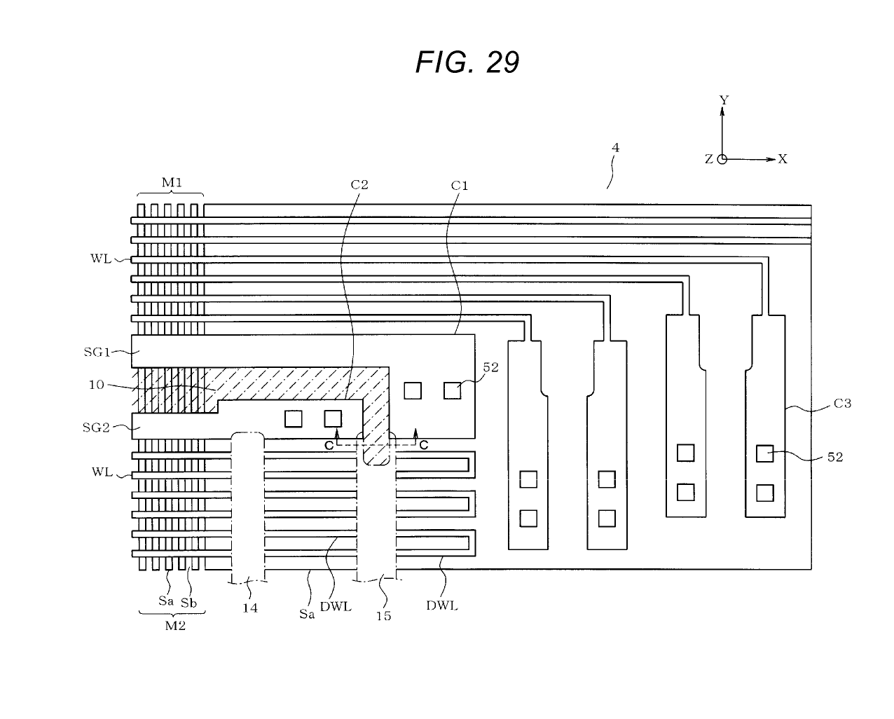

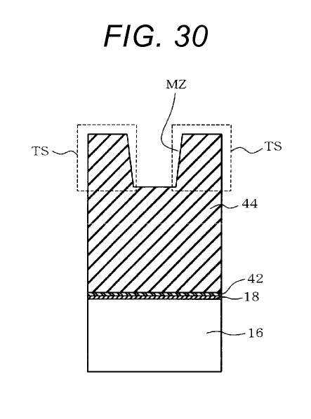

FIG. 29 is an example of a plan view showing a layout of the NAND-type flash memory device 1, according to a fourth embodiment. FIG. 30 shows an example of a longitudinal cross-sectional view taken along line C-C of FIG. 29. This configuration differs from the configurations discussed above in that a second word line dividing region 15 is formed so as to be connected to the inter-SG dividing region 10.

In FIG. 29, in the same manner as the first word line dividing region 14, the second word line dividing region 15 longitudinally crosses so as to be orthogonal to the plurality of dummy word lines DWL, and divides the word lines WL and the dummy word lines DWL. A width (width in the X direction in the figure) of the second word line dividing region 15 is set to be larger than the width of the inter-SG dividing region 10. The second word line dividing region 15 is formed so that the entire surface thereof is buried with the second insulating film 42 and the third insulating film 44 on the semiconductor substrate 16. The second word line dividing region 15 is formed by the same step as the first word line dividing region 14.

FIG. 30 shows a longitudinal cross-sectional view of the second word line dividing region 15 in the step described in FIGS. 21 and 22A and 22B. A recess, which is formed by the etching step used to form the inter-SG dividing region 10 exists in the center portion of the drawing. The groove MZ is formed when etching the third insulating film 44 and the first polysilicon film 22 in order, in the etching step of forming the inter-SG dividing region 10. A bottom portion of the groove MZ is in a position higher than the upper surface of the second insulating film 42. In addition, the third insulating film 44 includes a protrusion TS on both sides of the groove MZ.

Herein, in the step described in FIGS. 21 and 22, after performing the etching process used to form the inter-SG dividing region 10, a cleaning step for removing deposits generated by the etching process is performed, in some cases. A chemical solution used in this cleaning step is typically a chemical solution containing diluted hydrofluoric acid. The chemical solution used in this cleaning step is different from the chemical solution (which dissolves metal material such as tungsten) containing ammonia and a hydrogen peroxide solution described above. In this configuration, the chemical solution can only invade an outer side with respect to the first word line dividing region 14 in the X direction, in the memory cell region M2 of the device. Herein, in the first embodiment, the inter-SG dividing region 10 is buried with the third insulating film 44 or the like, and accordingly this substantially does not affect the memory cell region M2. However, the chemical solution can only invade into the first air gap AG1 in the formation region of the dummy word lines DWL from a groove MZS (see FIGS. 22A and 22B) formed in the inter-SG dividing region 10, in some cases.

When the subsequent process is performed while the chemical solution remains in the first air gap AG1, the malfunction may occur.

Here, in one embodiment, the second word line dividing region 15 is provided so as to be connected to the tip end portion of the inter-SG dividing region 10 which is formed in a substantially L shape. The second word line dividing region 15 is filled with the third insulating film 44. In addition, the second word line dividing region 15 is formed to be connected to the inter-SG dividing region 10, and the width of the inter-SG dividing region 10 in the Y direction is formed to be smaller than the width of the first word line dividing region 14 in the Y direction. Accordingly, the third insulating film 44 includes the protrusion TS, and the first air gap of the dummy word lines DWL and the groove MZS are divided by the protrusion TS. That is, the first air gap AG1 is blocked without being connected to the groove MZS. Therefore, by use of the second word line dividing region 15, it is possible to prevent the chemical solution from passing through the groove MZS of the inter-SG dividing region 10 and invading into the first air gap AG1 between the dummy word lines DWL.

The first word line dividing region 14 is formed between the second word line dividing region 15 and the memory cell region M2, and thus the invasion of the chemical solution is also prevented in this case. As described above, in one embodiment, since the invasion of the chemical solution can be dually prevented by the second word line dividing region 15 and the first word line dividing region 14, the invasion of the chemical solution into the memory cell region M2 can be more sufficiently shielded. Accordingly, it is possible to more effectively prevent device damage due to the chemical solution, and it is possible to provide a semiconductor device having high reliability and device yield.

### Other Embodiments

While the disclosure above primarily discusses a NAND-type flash memory device 1 as an example of the nonvolatile semiconductor memory device, this configuration is not intended to be limiting as to the scope of the invention described herein, since the embodiments discussed herein could also be used to form a NAND-type or NOR-type flash memory, EEPROM, or other similar memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a first memory block and a second memory block which are disposed adjacent to each other in a first direction, wherein
each of the first memory block and the second memory block includes bit lines which are disposed to extend in the first direction, word lines which are disposed to extend in a second direction crosswise to the bit lines, and memory cells connected to the word lines,
the first memory block includes a first selection gate transistor which is connected to an end of the memory cells of the first memory block,
the second memory block including a second selection gate transistor which is connected to an end of the memory cells of the second memory block,
a first selection gate line connected to the first selection gate transistor and a second selection gate line connected to the second selection gate transistor are adjacent to each other,
an end portion of the first selection gate line includes an L-shaped portion, the L-shaped portion having a first region extending in the second direction and a second region extending from the first region in the first direction at the end portion,
a first contact is disposed on the L-shaped portion of the first selection gate line, and
a distance in the first direction from a first edge of the first selection gate line, which is opposite to facing the second selection gate line, to a first edge of the second selection gate line, which is opposite to facing the first selection gate line, is equal to a width of the L-shaped portion, where the width is measured in the first direction from the first edge of the first selection gate line to a second edge of the second region that is opposite to the first edge of the first selection gate line.

2. The device according to claim 1, further comprising:
a first word line dividing region which divides the word lines,
wherein the first word line dividing region is disposed in the second memory block, and between the memory cells and the first contact of the second memory block, in the second direction.

3. The device according to claim 1, wherein
an end portion of the second selection gate line includes a linear portion,
the other end of the first selection gate line includes a linear portion, and
the other end of the second selection gate line includes an L-shaped portion, wherein the L-shaped portion of the second selection gate has a first region extending in a third direction, which is opposite to the second direction, and a second region extending from the first region of the second selection gate in a fourth direction, which is opposite to the first direction at the end portion.

4. The device according to claim 1, wherein
an end portion of the second selection gate line includes a linear portion,
the other end of the first selection gate line includes a linear portion,
the other end of the second selection gate includes an L-shaped portion, and
wherein the first selection gate line and the second selection gate line have point symmetry.

5. The device according to claim 1, further comprising:
a selection gate dividing region disposed between the first selection gate line and the second selection gate line.

6. The device according to claim 5, further comprising:
a first word line dividing region which divides the word lines, wherein the first word line dividing region is disposed in the second memory block, and
wherein the first word line dividing region contacts the selection gate dividing region.

7. The device according to claim 1, wherein the first contact is disposed at least in a position closer to the second edge of the second region of the first selection gate line than the first edge of the first selection gate line, in the first direction.

8. The device according to claim 1,
wherein an end portion of the second selection gate line includes a linear portion, and
a second contact is provided at least in the linear portion of the second selection gate line.

9. The device according to claim 8, further comprising:
a first word line dividing region which divides the plurality of word lines,
wherein the first word line dividing region is disposed on the memory cell side with respect to the second contact, in the second direction.

10. A nonvolatile semiconductor memory device, comprising:
a first memory block and a second memory block which are disposed adjacent to each other in a first direction, wherein
each of the first memory block and the second memory block includes bit lines which are disposed to extend in the first direction, word lines which are disposed to extend in a second direction crosswise to the bit lines, and memory cells connected to the word lines,
the first memory block includes a first selection gate transistor which is connected to an end of the memory cells of the first memory block,
the second memory block including a second selection gate transistor which is connected to an end of the memory cells of the second memory block,
a first selection gate line connected to the first selection gate transistor and a second selection gate line connected to the second selection gate transistor are adjacent to each other,
an end portion of the first selection gate line includes an L-shaped portion, the L-shaped portion having a first region extending in the second direction and a second region extending from the first region in the first direction at the end portion; and
a first contact that is disposed within the second region on the L-shaped portion of the first selection gate line.

11. The device according to claim 10, where the first contact is disposed a first distance in the first direction from a first edge of the first selection gate line, which is not facing the second selection gate line, to a first edge of the first contact, which is not facing the second selection gate line, and the first distance is greater than a width of the first region in the first direction.

12. The device according to claim 10, further comprising:
a first word line dividing region which divides the plurality of word lines,
wherein the first word line dividing region is disposed in the second memory block, and between the memory cells and the first contact of the second memory block, in the second direction.

13. The device according to claim 10, wherein
an end portion of the second selection gate line includes a linear portion,
the other end of the first selection gate line includes a linear portion, and
the other end of the second selection gate line includes an L-shaped portion, wherein the L-shaped portion of the second selection gate has a first region extending in third direction, which is opposite to the second direction, and a second region extending from the first region of the second selection gate in a fourth direction, which is opposite to the first direction at the end portion.

14. The device according to claim 10, wherein
the other end of the first selection gate includes a linear portion,
the other end of the second selection gate includes an L-shaped portion, and
the first selection gate and the second selection gate have point symmetry.

15. The device according to claim 10, further comprising:
a selection gate dividing region disposed between the first selection gate line and the second selection gate line.

16. The device according to claim 15, further comprising:
a first word line dividing region which divides the word lines, wherein the first word line dividing region is disposed in the second memory block, and
wherein the first word line dividing region contacts the selection gate dividing region.

17. The device according to claim 10, wherein an end portion of the second selection gate line includes a linear portion, and
the first contact is disposed at least in a position closer to the second edge of the second region of the first selection gate line than the first edge of the first selection gate line of the first selection gate, in the first direction, and a second contact is provided at least in the linear portion of the second selection gate line.
